(19) United States
(12) Patent Application Publication
(10) Pub. No.: US 2026/0182412 A1
(43) Pub. Date: Jun. 25, 2026

(54) PACKAGE COMPRISING A DEVICE WITH A CAPACITOR COMPRISING VERTICALLY ALIGNED CAPACITOR INTERCONNECTS

(71) Applicant: QUALCOMM Incorporated, San Diego, CA (US)

(72) Inventors: Ryan LANE, San Diego, CA (US); Li-Sheng WENG, San Diego, CA (US)

(21) Appl. No.: 18/990,958

(22) Filed: Dec. 20, 2024

(51) Int. Cl. H01L 23/538; H01L 23/14; H01L 25/18; H10D 1/68

(52) U.S. Cl. CPC H10W 70/65; H10D 1/692; H10W 70/611; H10W 70/685; H10W 90/00; H10W 70/698

(57) ABSTRACT

A package comprising a package substrate comprising at least one dielectric layer; a plurality of interconnects; a passive device located at least partially in the at least one dielectric layer, wherein the passive device comprises a bridge comprising a plurality of bridge interconnects; and a capacitor comprising a plurality of capacitor interconnects that are vertically aligned; and an integrated device coupled to the package substrate.

### FIELD

Various features relate to packages with a passive device.

### BACKGROUND

A package may include a substrate, an interposer and/or integrated devices. These components are coupled together to provide a package that may perform various electrical functions. There is an ongoing need to provide reliable and/or better performing packages. Moreover, there is also an ongoing need to reduce the overall size of the packages.

### SUMMARY

Various features relate to packages with passive devices.

One example provides a package comprising a package substrate comprising at least one dielectric layer; a plurality of interconnects; a passive device located at least partially in the at least one dielectric layer, wherein the passive device comprises a bridge comprising a plurality of bridge interconnects; and a capacitor comprising a plurality of capacitor interconnects that are vertically aligned; and an integrated device coupled to the package substrate.

Another example provides a package comprising a package interposer comprising: a first metallization portion; a second metallization portion; and a passive device located between the first metallization portion and the second metallization portion, wherein the passive device comprises: a bridge comprising a plurality of bridge interconnects; and a capacitor comprising a plurality of capacitor interconnects that are vertically aligned; and an integrated device coupled to the package interposer.

Another example provides a package comprising a package interposer comprising: a first metallization portion; a second metallization portion; and an active device located between the first metallization portion and the second metallization portion, wherein the active device comprises: a memory; and a capacitor comprising a plurality of capacitor interconnects that are vertically aligned; and an integrated device coupled to the package interposer.

Another example provides a package comprising a package substrate comprising: at least one dielectric layer; a plurality of interconnects; an active device located at least partially in the at least one dielectric layer, wherein the active device comprises: a memory; and a capacitor comprising a plurality of capacitor interconnects that are vertically aligned; and an integrated device coupled to the package substrate and the active device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a passive device that includes a bridge and a capacitor.

FIG. 2 illustrates an exemplary cross sectional profile view of an active device that includes a memory, a capacitor and a bridge.

FIG. 3 illustrates an exemplary cross sectional profile view of a package comprising a passive device and/or an active device.

FIG. 4 illustrates an exemplary cross sectional profile view of a package comprising a passive device and/or an active device.

FIG. 5 illustrates an exemplary cross sectional profile view of a package comprising a passive device and/or an active device.

FIG. 6 illustrates an exemplary sequence for fabricating an active device that includes a memory, a capacitor and a bridge.

FIG. 7 illustrates an exemplary sequence for fabricating a passive device that includes a bridge and a capacitor.

FIGS. 8A-8E illustrate an exemplary sequence for fabricating a package comprising a passive device and/or an active device.

FIG. 9 illustrates an exemplary flow chart of a method for fabricating a package comprising a passive device and/or an active device.

FIGS. 10A-10E illustrate an exemplary sequence for fabricating a package comprising a passive device and/or an active device.

FIG. 11 illustrates an exemplary flow chart of a method for fabricating a package comprising a passive device and/or an active device.

FIGS. 12A-12C illustrate an exemplary sequence for fabricating a package comprising a passive device and/or an active device.

FIG. 13 illustrates an exemplary flow chart of a method for fabricating a package comprising a passive device and/or an active device.

FIGS. 14A-14B illustrate an exemplary sequence for fabricating a metallization portion.

FIG. 15 illustrates an exemplary flow chart of a method for fabricating a metallization portion.

FIG. 16 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a package substrate comprising at least one dielectric layer; a plurality of interconnects; a passive device located at least partially in the at least one dielectric layer, wherein the passive device comprises a bridge comprising a plurality of bridge interconnects; and a capacitor comprising a plurality of capacitor interconnects that are vertically aligned; and an integrated device coupled to the package substrate.

### Exemplary Packages Comprising a Passive Device And/or an Active Device

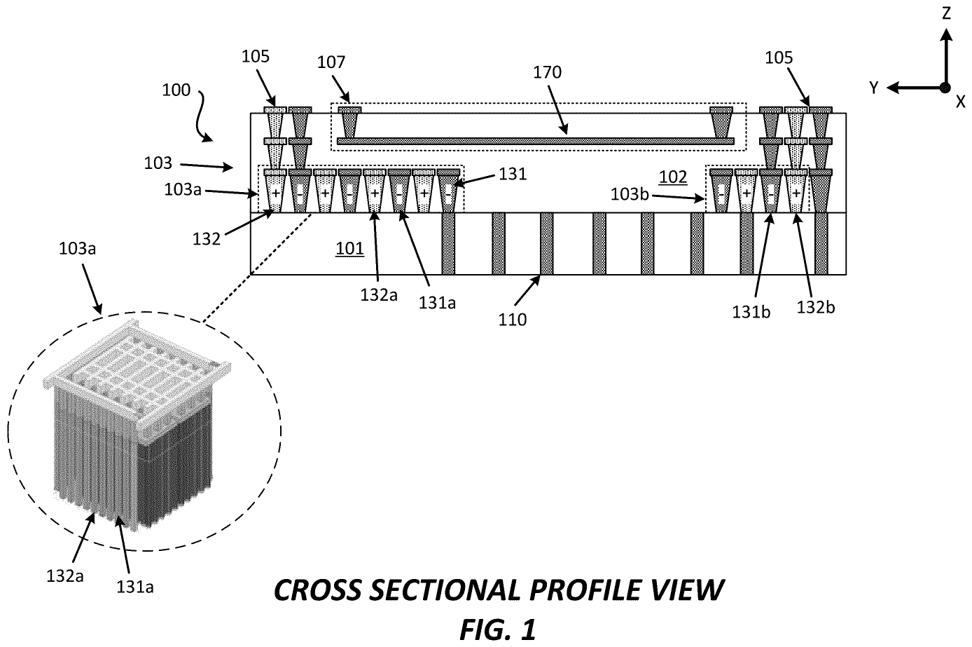

FIG. 1 illustrates a cross sectional profile view of a passive device 100 that includes a capacitor and a bridge. The passive device 100 includes a substrate 101 (e.g., passive device substrate, passive device silicon substrate), a plurality of capacitors 103 and a bridge 107. The passive device 100 may also include a plurality of through substrate via interconnects 110. The plurality of through substrate via interconnects 110 may extend through the substrate 101. The plurality of through substrate via interconnects 110 may be coupled to a plurality of interconnects 105.

The plurality of capacitors 103 includes a capacitor 103a and a capacitor 103b. The capacitor 103a includes a plurality of capacitor interconnects 131a and a plurality of capacitor interconnects 132a. The plurality of capacitor interconnects 131a may include a plurality of capacitor via interconnects. The plurality of capacitor interconnects 131a may be configured as a plurality of cathode capacitor via interconnects. The plurality of capacitor interconnects 132a may be configured as a plurality of cathode capacitor via interconnects. The plurality of capacitor interconnects 131a and the plurality of capacitor interconnects 132a may be arranged as a matrix of capacitor interconnects that alternate between an interconnect from the plurality of capacitor interconnects 131a and an interconnect from the plurality of capacitor interconnects 132a. The plurality of capacitor interconnects 131a and/or the plurality of capacitor interconnects 132a may be columns of interconnects (e.g., vertically aligned interconnects, vertical stacks of via interconnects and pad interconnects) that are arranged in several rows, where each row include alternating cathode capacitor interconnects and anode capacitor interconnects. The capacitance of the capacitor 103a may be defined by the number and/or the size of the plurality of capacitor interconnects 131a and/or the number and/or the size of the plurality of capacitor interconnects 132a. The capacitor 103a may be formed over the substrate 101. In some implementations, the capacitor 103a may be coupled to the plurality of through substrate via interconnects 110. The capacitor 103a may be coupled to a plurality of interconnects 105. The capacitor 103a and/or the plurality of interconnects 105 may be located at least partially in the at least one dielectric layer 102. The at least one dielectric layer 102 may be coupled to the substrate 101. In some implementations, the at least one dielectric layer 102 and the substrate 101 may be considered part of the capacitor 103a. In some implementations, the plurality of capacitor interconnects 131a may include vertically stacked via interconnects and pad interconnects. In some implementations, the plurality of capacitor interconnects 132a may include vertically stacked via interconnects and pad interconnects. The plurality of interconnects 105 may be coupled to the plurality of capacitor interconnects 131a and/or the plurality of capacitor interconnects 132a. FIG. 1 also illustrates an exemplary conceptual angled view of the capacitor 103a that includes vertically aligned capacitor interconnects (e.g., vertically aligned capacitor plates).

The capacitor 103b includes a plurality of capacitor interconnects 131b and a plurality of capacitor interconnects 132b. The plurality of capacitor interconnects 131b may include a plurality of capacitor via interconnects. The plurality of capacitor interconnects 131b may be configured as a plurality of cathode capacitor via interconnects. The plurality of capacitor interconnects 132b may be configured as a plurality of cathode capacitor via interconnects. The plurality of capacitor interconnects 131b and the plurality of capacitor interconnects 132b may be arranged as a matrix of capacitor interconnects that alternate between an interconnect from the plurality of capacitor interconnects 131b and an interconnect from the plurality of capacitor interconnects 132b. The plurality of capacitor interconnects 131b and/or the plurality of capacitor interconnects 132b may be columns of interconnects (e.g., vertically aligned interconnects, vertical stacks of via interconnects and pad interconnects) that are arranged in several rows, where each row include alternating cathode capacitor interconnects and anode capacitor interconnects. The capacitance of the capacitor 103b may be defined by the number and/or the size of the plurality of capacitor interconnects 131b and/or the number and/or the size of the plurality of capacitor interconnects 132b. The capacitor 103b may be formed over the substrate 101. In some implementations, the capacitor 103b may be coupled to the plurality of through substrate via interconnects 110. The capacitor 103b may be coupled to a plurality of interconnects 105. The capacitor 103b and/or the plurality of interconnects 105 may be located at least partially in the at least one dielectric layer 102. The at least one dielectric layer 102 may be coupled to the substrate 101. In some implementations, the at least one dielectric layer 102 and the substrate 101 may be considered part of the capacitor 103b. In some implementations, the plurality of capacitor interconnects 131b may include vertically stacked via interconnects and pad interconnects. In some implementations, the plurality of capacitor interconnects 132b may include vertically stacked via interconnects and pad interconnects. The plurality of interconnects 105 may be coupled to the plurality of capacitor interconnects 131b and/or the plurality of capacitor interconnects 132b.

In some implementations, the capacitor 103a may be electrically coupled to the capacitor 103b in series and/or in parallel. Other capacitor(s) may be similar to the capacitor 103a and/or the capacitor 103b, but may include a different number of capacitor interconnects and/or may include a different design.

The bridge 107 is located at least partially in the at least one dielectric layer 102. The bridge 107 may include a plurality of bridge interconnects 170. A part of the at least one dielectric layer 102 may be considered part of the bridge 107. In some implementations, the substrate 101 may be considered part of the bridge 107. The bridge 107 may be located over part of the plurality of capacitors 103. The bridge 107 may be configured to provide several electrical paths to two or more integrated devices. The plurality of capacitors 103 and/or the bridge 107 may be fabricated using a back end of line (BOEL) process.

The passive device 100 provides a compact design and/or configuration of a passive device that may perform several functions, which can help reduce the overall size of devices. As will be further described below, the passive device 100 may be implemented in a package, a package substrate and/or a package interposer.

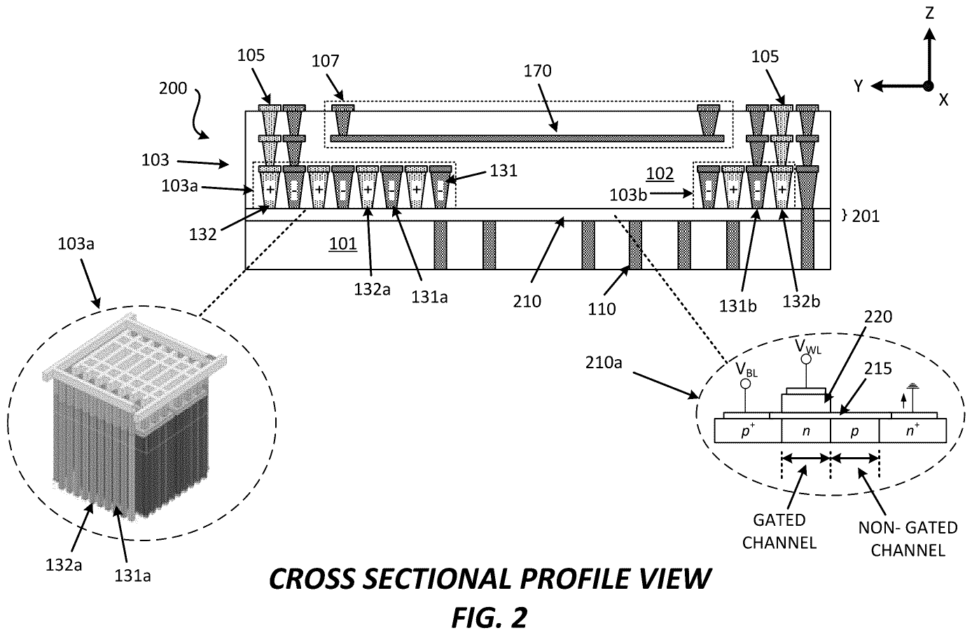

FIG. 2 illustrates a cross sectional profile view of an active device 200 that includes a memory, a capacitor and a bridge. The active device 200 includes a substrate 101 (e.g., passive device substrate, passive device silicon substrate), a memory 201, a plurality of capacitors 103 and a bridge 107. The active device 200 may also include a plurality of through substrate via interconnects 110. The plurality of through substrate via interconnects 110 may extend through the substrate 101. The plurality of through substrate via interconnects 110 may be coupled to a plurality of interconnects 105.

The memory 201 may be formed and coupled to the substrate 101. The memory 201 may be formed in part of the substrate 101. The memory 201 may be an active component of the active device 200. The memory 201 may include a plurality of logic cells 210. The plurality of logic cells 210 may include a logic cell 210a. The logic cell 210a may be a memory logic cell. The logic cell 210a may include a transistor. A transistor may include a gate (220), n-wells, p-wells, one or more channels, a gate oxide (215) and interconnects. A transistor may include shallow trench isolation, wells, a gate, a source and a drain. Different implementations may use different design and/or configurations for a transistor. The memory 201 may include a plurality of transistors. A logic cell (e.g., memory logic cell) may include a plurality of transistors. The memory 201 may be coupled to the plurality of interconnects 105. The memory 201 may be coupled to the plurality of through substrate via interconnects 110. In some implementations, the memory 201 may be a memory portion of the active device 200. In some implementations, the memory 201 may be a memory layer of the active device 200.

The plurality of capacitors 103 include a capacitor 103a and a capacitor 103b. The capacitor 103a includes a plurality of capacitor interconnects 131a and a plurality of capacitor interconnects 132a. The plurality of capacitor interconnects 131a may include a plurality of capacitor via interconnects. The plurality of capacitor interconnects 131a may be configured as a plurality of cathode capacitor via interconnects. The plurality of capacitor interconnects 132a may be configured as a plurality of cathode capacitor via interconnects. The plurality of capacitor interconnects 131a and the plurality of capacitor interconnects 132a may be arranged as a matrix of capacitor interconnects that alternate between an interconnect from the plurality of capacitor interconnects 131a and an interconnect from the plurality of capacitor interconnects 132a. The plurality of capacitor interconnects 131a and/or the plurality of capacitor interconnects 132a may be columns of interconnects that are arranged in several rows, where each row include alternating cathode capacitor interconnects and anode capacitor interconnects. The capacitance of the capacitor 103a may be defined by the number and/or the size of the plurality of capacitor interconnects 131a and/or the number and/or the size of the plurality of capacitor interconnects 132a. The capacitor 103a may be formed over the substrate 101. In some implementations, the capacitor 103a may be coupled to the plurality of through substrate via interconnects 110. The capacitor 103a may be coupled to a plurality of interconnects 105. The capacitor 103a and/or the plurality of interconnects 105 may be located at least partially in the at least one dielectric layer 102. The at least one dielectric layer 102 may be coupled to the substrate 101. In some implementations, the at least one dielectric layer 102 and the substrate 101 may be considered part of the capacitor 103a. In some implementations, the plurality of capacitor interconnects 131a may include vertically stacked via interconnects and pad interconnects. In some implementations, the plurality of capacitor interconnects 132a may include vertically stacked via interconnects and pad interconnects. The plurality of interconnects 105 may be coupled to the plurality of capacitor interconnects 131a and/or the plurality of capacitor interconnects 132a. FIG. 2 also illustrates an exemplary conceptual angled view of the capacitor 103a that includes vertically aligned capacitor interconnects (e.g., vertically aligned capacitor plates).

The capacitor 103b includes a plurality of capacitor interconnects 131b and a plurality of capacitor interconnects 132b. The plurality of capacitor interconnects 131b may include a plurality of capacitor via interconnects. The plurality of capacitor interconnects 131b may be configured as a plurality of cathode capacitor via interconnects. The plurality of capacitor interconnects 132b may be configured as a plurality of cathode capacitor via interconnects. The plurality of capacitor interconnects 131b and the plurality of capacitor interconnects 132b may be arranged as a matrix of capacitor interconnects that alternate between an interconnect from the plurality of capacitor interconnects 131b and an interconnect from the plurality of capacitor interconnects 132b. The plurality of capacitor interconnects 131b and/or the plurality of capacitor interconnects 132b may be columns of interconnects that are arranged in several rows, where each row include alternating cathode capacitor interconnects and anode capacitor interconnects. The capacitance of the capacitor 103b may be defined by the number and/or the size of the plurality of capacitor interconnects 131b and/or the number and/or the size of the plurality of capacitor interconnects 132b. The capacitor 103b may be formed over the substrate 101. In some implementations, the capacitor 103b may be coupled to the plurality of through substrate via interconnects 110. The capacitor 103b may be coupled to a plurality of interconnects 105. The capacitor 103b and/or the plurality of interconnects 105 may be located at least partially in the at least one dielectric layer 102. The at least one dielectric layer 102 may be coupled to the substrate 101. In some implementations, the at least one dielectric layer 102 and the substrate 101 may be considered part of the capacitor 103b. In some implementations, the plurality of capacitor interconnects 131b may include vertically stacked via interconnects and pad interconnects. In some implementations, the plurality of capacitor interconnects 132b may include vertically stacked via interconnects and pad interconnects. The plurality of interconnects 105 may be coupled to the plurality of capacitor interconnects 131b and/or the plurality of capacitor interconnects 132b.

In some implementations, the capacitor 103a may be electrically coupled to the capacitor 103b in series and/or in parallel. Other capacitor(s) may be similar to the capacitor 103a and/or the capacitor 103b, but may include a different number of capacitor interconnects and/or may include a different design.

The bridge 107 is located at least partially in the at least one dielectric layer 102. The bridge 107 may include a plurality of bridge interconnects 170. A part of the at least one dielectric layer 102 may be considered part of the bridge 107. In some implementations, the substrate 101 may be considered part of the bridge 107. The bridge 107 may be located over part of the plurality of capacitors 103. The bridge 107 may be configured to provide several electrical paths to two or more integrated devices. The plurality of capacitors 103 and/or the bridge 107 may be fabricated using a back end of line (BOEL) process.

In some implementations, the active device 200 may include the memory 201 and the plurality of capacitors 103. The bridge 107 may be optional in the active device 200. The active device 200 provides a compact design and/or configuration of an active device that may perform several functions, which can help reduce the overall size of devices. As will be further described below, the active device 200 may be implemented in a package, a package substrate and/or a package interposer.

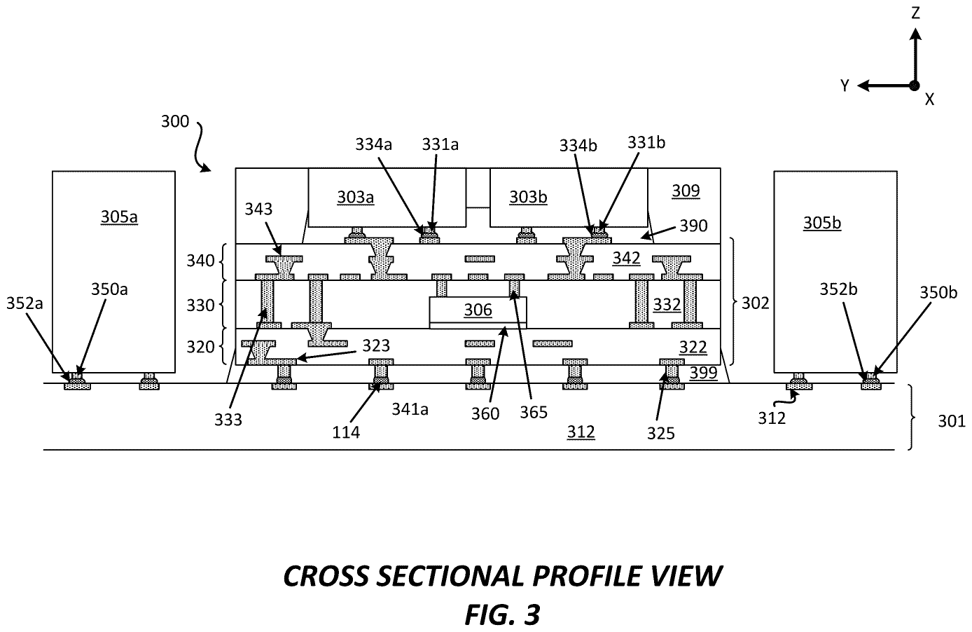

FIG. 3 illustrates a cross sectional profile view of a package 300 that includes a package interposer and an embedded device, where the embedded device is a passive device or an active device. The package 300 is coupled to a board 301 through a plurality of solder interconnects 114. The board 301 includes at least one board dielectric layer 310 and a plurality of board interconnects 312. The board 301 may include a printed circuit board (PCB). In some implementations, instead of the board 301, the package 300 may be coupled to a substrate (e.g., laminated substrate) through the plurality of solder interconnects 114.

The package 300 includes a package interposer 302, an integrated device 303a, an integrated device 303b, an underfill 390 and an encapsulation layer 309. In some implementations, the integrated device 303a may include a first system on chip (SoC). In some implementations, the integrated device 303b may include a second system on chip (SoC).

The package interposer 302 may be a package substrate. The package interposer 302 includes a metallization portion 320, an encapsulated portion 330, a metallization portion 340, and a plurality of pillar interconnects 325. In some implementations, the metallization portion 320 may be a first metallization portion and the metallization portion 340 may be a second metallization portion. The encapsulated portion 330 is coupled to the metallization portion 320 and the metallization portion 340. The encapsulated portion 330 is located between the metallization portion 320 and the metallization portion 340. The metallization portion 320 includes at least one dielectric layer 322 and a plurality of metallization interconnects 323. The at least one dielectric layer 322 may include prepreg and/or polyimide. The metallization portion 340 includes at least one dielectric layer 342 and a plurality of metallization interconnects 343. The at least one dielectric layer 342 may include prepreg and/or polyimide. The plurality of pillar interconnects 325 are coupled to the plurality of metallization interconnects 323 of the metallization portion 320. The plurality of pillar interconnects 325 may be considered part of the metallization portion 320. The plurality of pillar interconnects 325 are coupled to the plurality of solder interconnects 114.

The encapsulated portion 330 includes an encapsulation layer 332 and a plurality of post interconnects 333. The plurality of post interconnects 333 may include a plurality of through mold vias (TMVs). The encapsulated portion 330 also includes a device 306. The device 306 may represent the passive device 100 or the active device 200. The device 306 may be located at least partially in the encapsulation layer 332. Thus, the encapsulation layer 332 may at least partially encapsulate the device 306 and/or the plurality of post interconnects 333.

The device 306 may include a silicon bridge, as described in the passive device 100 and/or the active device 200. The device 306 may include a bridge substrate (e.g., silicon substrate, silicon bridge substrate) and a plurality of bridge interconnects. The device 306 may also include at least one bridge dielectric layer. The device 306 may include a plurality of post interconnects 365. The device 306 may include a capacitor, as described in the passive device 100 and/or the active device 200. The device 306 may include a memory, as described in the active device 200. In some implementations, there may be more than one devices (e.g., one or more devices 306). In such instances, the one or more devices 306 may represent different combinations of the passive device 100 and/or the active device 200. For example, when there are two devices 306, one device may represent a passive device 100 and another device may represent an active device 200. In another example, when there are two devices 306, both devices may each represent a passive device 100. In yet another example, when there are two devices 306, both devices may each represent an active device 200.

In some implementations, the integrated device 303a may be configured to be electrically coupled to a capacitor (e.g., 103a) from the device 306, and the integrated device 303b may be configured to be electrically coupled to another capacitor (e.g., 103b) from the device 306. In some implementations, the integrated device 303a may be configured to be electrically coupled to a memory (e.g., 201) from the device 306, and the integrated device 303b may be configured to be electrically coupled to a memory (e.g., 201) from the device 306.

The encapsulation layer 332 may include a mold, a resin, an epoxy and/or a filler. The encapsulation layer 332 may be a means for encapsulation. The encapsulation layer 332 may be provided by using a compression and transfer molding process, a sheet molding process, or a liquid molding process. A back side of the device 306 is coupled to the metallization portion 320 through an adhesive 360 (e.g., die attach film (DAF)).

The plurality of post interconnects 333 extend through the encapsulation layer 332. The plurality of post interconnects 333 are coupled to the metallization portion 320 and the metallization portion 340. For example, the plurality of post interconnects 333 may be coupled to (i) the plurality of metallization interconnects 323 of the metallization portion 320 and (ii) the plurality of metallization interconnects 343 of the metallization portion 340. The plurality of post interconnects 365 are coupled to and touch the device 306 and the plurality of metallization interconnects 343 of the metallization portion 340.

The encapsulation layer 332, the device 306, the plurality of post interconnects 333, the plurality of post interconnects 345a, the plurality of post interconnects 345b and the plurality of post interconnects 365 are located between the metallization portion 320 and the metallization portion 340. The encapsulation layer 332 is coupled to the metallization portion 320 and the metallization portion 340. In some implementations, some of the metallization interconnects from the plurality of metallization interconnects 323 may be at least partially encapsulated by the encapsulation layer 332.

The integrated device 303a is coupled to a first surface of the metallization portion 340 through a plurality of pillar interconnects 331a and a plurality of solder interconnects 334a. The plurality of pillar interconnects 331a and/or the plurality of solder interconnects 334a may represent a plurality of bump interconnects. The integrated device 303b is coupled to a first surface of the metallization portion 340 through a plurality of pillar interconnects 331b and a plurality of solder interconnects 334b. The plurality of pillar interconnects 331b and/or the plurality of solder interconnects 334b may represent a plurality of bump interconnects.

An underfill 390 is located between the integrated device 303a and the package interposer 302. The underfill 390 is located between the integrated device 303b and the package interposer 302. In some implementations, the underfill 390 may include composite material comprising an epoxy polymer with filler. An encapsulation layer 309 may be located over the package interposer 302. The package interposer 302 may be coupled to the underfill 390, the integrated device 303a, the integrated device 303b, the integrated device 305a, and/or the integrated device 305b. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may be different from the underfill 390. For example, the encapsulation layer 309 may include a different material and/or a different composition of material from the underfill 390. An underfill 399 may be located between the metallization portion 320 of the package interposer 302 and the board 301. The underfill 399 may be similar to the underfill 390,

In some implementations, an electrical path between the integrated device 303a and the integrated device 303b may include the metallization portion 340. In some implementations, an electrical path between the integrated device 303a and the integrated device 303b may include the metallization portion 340 and the device 306. For example, an electrical path between the integrated device 303a and the integrated device 303b may include (i) a pillar interconnect from the plurality of pillar interconnects 331a, (ii) a solder interconnect from the plurality of solder interconnects 334a, (iii) at least one metallization interconnect from the plurality of metallization interconnects 343, (iv) a post interconnect from the plurality of post interconnects 365, (v) the device 306, (vi) another post interconnect from the plurality of post interconnects 365, (vii) at least one other metallization interconnect from the plurality of metallization interconnects 343, (viii) a solder interconnect from the plurality of solder interconnects 334b and/or (ix) a pillar interconnect from the plurality of pillar interconnects 331b.

In some implementations, an electrical path between the metallization portion 320 and the metallization portion 340, may include at least one post interconnect from the plurality of post interconnects 333.

The integrated device 305a is coupled to the board 301 through a plurality of pillar interconnects 350a and/or a plurality of solder interconnects 352a. The integrated device 305a is coupled to the board 301 through a plurality of pillar interconnects 350b and/or a plurality of solder interconnects 352b. The integrated device 305a and/or the integrated device 305b may include a memory (e.g., memory die, memory integrated device). In some implementations, the integrated device 305a may include a first memory integrated device (e.g., first high density memory die, first high bandwidth memory). In some implementations, the integrated device 305b may include a second memory integrated device (e.g., second high density memory die, second high bandwidth memory). The integrated device 305a is configured to be electrically coupled to the integrated device 303a and/or the integrated device 303b. The integrated device 305b is configured to be electrically coupled to the integrated device 303a and/or the integrated device 303b.

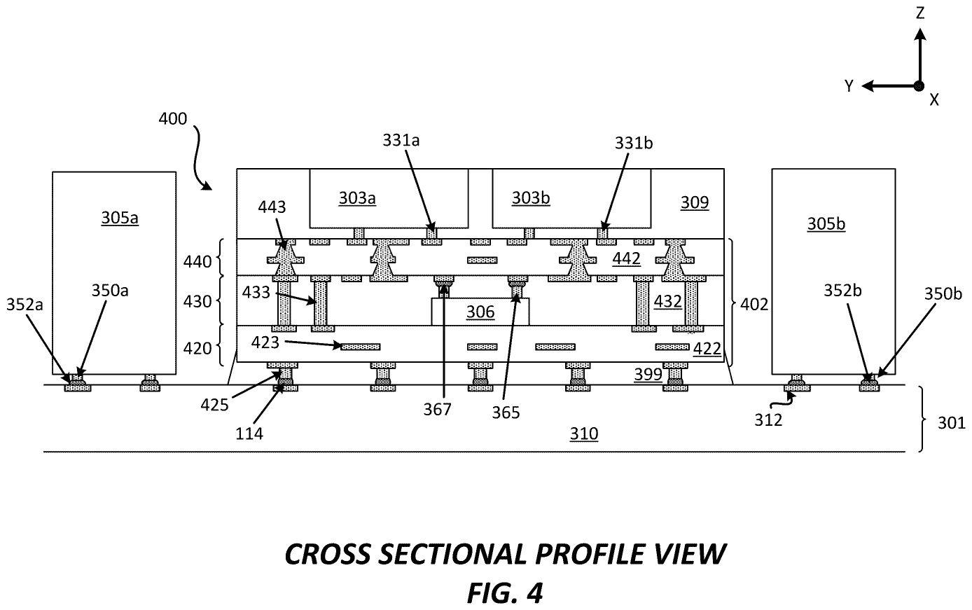

FIG. 4 illustrates a cross sectional profile view of a package 400 that includes a package interposer and an embedded device, where the embedded device is a passive device or an active device. The package 400 is coupled to a board 301 through a plurality of solder interconnects 114. In some implementations, instead of the board 301, the package 400 may be coupled to a substrate (e.g., laminated substrate) through the plurality of solder interconnects 114.

The package 400 is similar to the package 300 of FIG. 3, and may include similar components that are arranged in a similar manner as described for the package 300. The package 400 includes a package interposer 402, an integrated device 303a, an integrated device 303b, and an encapsulation layer 309. In some implementations, the integrated device 303a may include a first system on chip (SoC). In some implementations, the integrated device 303b may include a second system on chip (SoC).

The package interposer 402 may be a package substrate. The package interposer 402 includes a metallization portion 420, an encapsulated portion 430, a metallization portion 440, and a plurality of pillar interconnects 425. In some implementations, the metallization portion 420 may be a first metallization portion and the metallization portion 440 may be a second metallization portion. The encapsulated portion 430 is coupled to the metallization portion 420 and the metallization portion 440. The encapsulated portion 430 is located between the metallization portion 420 and the metallization portion 440. The metallization portion 420 includes at least one dielectric layer 422 and a plurality of metallization interconnects 423. The at least one dielectric layer 422 may include prepreg and/or polyimide. The metallization portion 440 includes at least one dielectric layer 442 and a plurality of metallization interconnects 443. The at least one dielectric layer 442 may include prepreg and/or polyimide. The plurality of pillar interconnects 425 are coupled to the plurality of metallization interconnects 423 of the metallization portion 420. The plurality of pillar interconnects 425 may be considered part of the metallization portion 420. The plurality of pillar interconnects 425 are coupled to the plurality of solder interconnects 114.

The encapsulated portion 430 includes an encapsulation layer 432 and a plurality of post interconnects 433. The encapsulated portion 430 also includes a device 306. The device 306 may represent the passive device 100 or the active device 200. The device 306 may be located at least partially in the encapsulation layer 432. Thus, the encapsulation layer 432 may at least partially encapsulate the device 306 and/or the plurality of post interconnects 433.

The device 306 may include a silicon bridge, as described in the passive device 100 and/or the active device 200. The device 306 may include a bridge substrate (e.g., silicon substrate, silicon bridge substrate) and a plurality of bridge interconnects. The device 306 may also include at least one bridge dielectric layer. The device 306 may include a plurality of post interconnects 365. The device 306 may include a capacitor, as described in the passive device 100 and/or the active device 200. The device 306 may include a memory, as described in the active device 200. In some implementations, there may be more than one devices (e.g., one or more devices 306). In such instances, the one or more devices 306 may represent different combinations of the passive device 100 and/or the active device 200. For example, when there are two devices 306, one device may represent a passive device 100 and another device may represent an active device 200. In another example, when there are two devices 306, both devices may each represent a passive device 100. In yet another example, when there are two devices 306, both devices may each represent an active device 200.

In some implementations, the integrated device 303a may be configured to be electrically coupled to a capacitor (e.g., 103a) from the device 306, and the integrated device 303b may be configured to be electrically coupled to another capacitor (e.g., 103b) from the device 306. In some implementations, the integrated device 303a may be configured to be electrically coupled to a memory (e.g., 201) from the device 306, and the integrated device 303b may be configured to be electrically coupled to a memory (e.g., 201) from the device 306.

The encapsulation layer 432 may include a mold, a resin, an epoxy and/or a filler. The encapsulation layer 432 may be a means for encapsulation. The encapsulation layer 432 may be provided by using a compression and transfer molding process, a sheet molding process, or a liquid molding process. A back side of the device 306 is coupled to and touching the metallization portion 420.

The plurality of post interconnects 433 extend through the encapsulation layer 432. The plurality of post interconnects 433 may include a plurality of through mold vias (TMVs). The plurality of post interconnects 433 are coupled to the metallization portion 420 and the metallization portion 440. For example, the plurality of post interconnects 433 may be coupled to (i) the plurality of metallization interconnects 423 of the metallization portion 420 and (ii) the plurality of metallization interconnects 443 of the metallization portion 440.

The front side of the device 306 is coupled to the plurality of metallization interconnects 443 of the metallization portion 440 through the plurality of post interconnects 365 and the plurality of solder interconnects 367. The back side of the device 306 is coupled to and touch the metallization portion 420. In some implementations, a back side of the device 306 is the side that includes a bridge die substrate (e.g., silicon bridge die substrate).

The encapsulation layer 432, the device 306, the plurality of post interconnects 433, the plurality of post interconnects 445a, the plurality of post interconnects 445b, and the plurality of post interconnects 365 are located between the metallization portion 420 and the metallization portion 440. The encapsulation layer 432 is coupled to the metallization portion 420 and the metallization portion 440. In some implementations, some of the metallization interconnects from the plurality of metallization interconnects 423 may be at least partially encapsulated by the encapsulation layer 432.

The integrated device 303a may be coupled to a first surface of the metallization portion 440 through a plurality of pillar interconnects 331a (and/or pad interconnects of the integrated device 303a. The integrated device 303b may be coupled to a first surface of the metallization portion 440 through a plurality of pillar interconnects 331b (and/or pad interconnects of the integrated device 303b.

An encapsulation layer 309 may be located over the package interposer 402. The package interposer 402 may be coupled to the integrated device 303a, the integrated device 303b and the encapsulation layer 309. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process.

In some implementations, an electrical path between the integrated device 303a and the integrated device 303b may include the metallization portion 440. In some implementations, an electrical path between the integrated device 303a and the integrated device 303b may include the metallization portion 440 and the device 306. For example, an electrical path between the integrated device 303a and the integrated device 303b may include (i) a pillar interconnect from the plurality of pillar interconnects 331a, (ii) at least one metallization interconnect from the plurality of metallization interconnects 443, (iii) a solder interconnect from the plurality of solder interconnects 367, (iv) a post interconnect from the plurality of post interconnects 365, (v) the device 306, (vi) another post interconnect from the plurality of post interconnects 365, (vii) another solder interconnect from the plurality of solder interconnects 367, (viii) at least one other metallization interconnect from the plurality of metallization interconnects 443, and/or (ix) a pillar interconnect from the plurality of pillar interconnects 331b.

In some implementations, an electrical path between the metallization portion 420 and the metallization portion 440, may include at least one post interconnect from the plurality of post interconnects 433.

The integrated device 305a is coupled to the board 301 through a plurality of pillar interconnects 350a and/or a plurality of solder interconnects 352a. The integrated device 305a is coupled to the board 301 through a plurality of pillar interconnects 350b and/or a plurality of solder interconnects 352b. The integrated device 305a and/or the integrated device 305b may include a memory (e.g., memory die, memory integrated device). In some implementations, the integrated device 305a may include a first memory integrated device (e.g., first high density memory die, first high bandwidth memory). In some implementations, the integrated device 305b may include a second memory integrated device (e.g., second high density memory die, second high bandwidth memory). The integrated device 305a is configured to be electrically coupled to the integrated device 303a and/or the integrated device 303b. The integrated device 305b is configured to be electrically coupled to the integrated device 303a and/or the integrated device 303b.

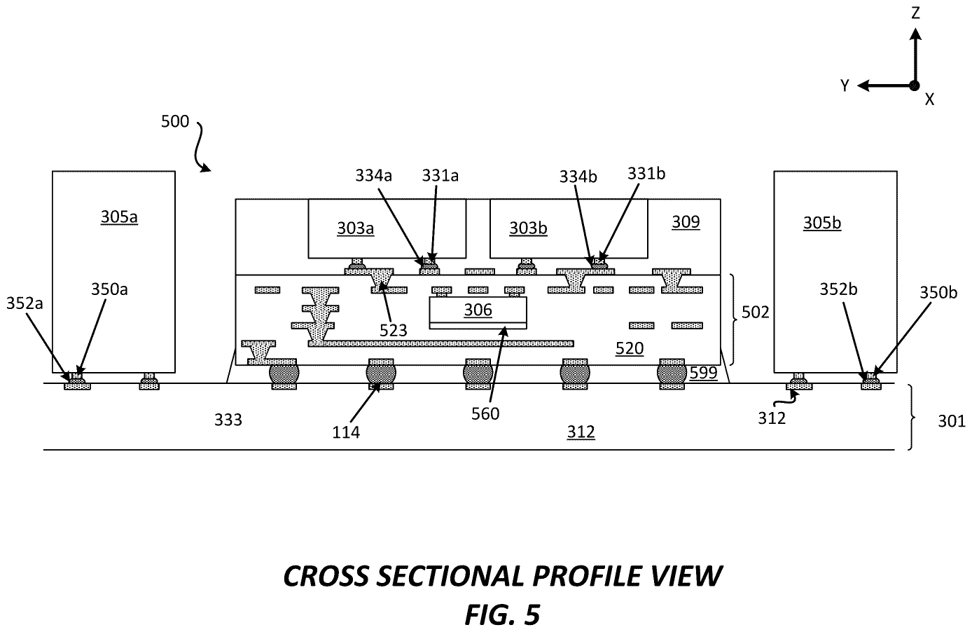

FIG. 5 illustrates a cross sectional profile view of a package 500 that includes a package substrate and an embedded device, where the embedded device is a passive device or an active device. The package 500 is coupled to a board 301 through a plurality of solder interconnects 114. In some implementations, instead of the board 301, the package 400 may be coupled to a substrate (e.g., laminated substrate) through the plurality of solder interconnects 114.

The package 500 includes a package substrate 502, an integrated device 303a, an integrated device 303b, and an encapsulation layer 309. In some implementations, the integrated device 303a may include a first system on chip (SoC). In some implementations, the integrated device 303b may include a second system on chip (SoC).

The package substrate 502 includes at least one dielectric layer 520, a plurality of interconnects 523. A device 306 may be located in the package substrate 502. The device 306 may represent the passive device 100 or the active device 200. The device 306 may be coupled to the plurality of interconnects 523. The device 306 may be located in a cavity of the package substrate 502. The cavity may be at least partially filled with a dielectric layer. An adhesive 560 may be coupled to the device 306. The adhesive 560 may be coupled to the at least one dielectric layer 520.

The integrated device 303a may be coupled to the plurality of interconnects 523 of the package substrate 502 through a plurality of pillar interconnects 331a and a plurality of solder interconnects 334a. The integrated device 303b may be coupled to the plurality of interconnects 523 of the package substrate 502 through a plurality of pillar interconnects 331b and a plurality of solder interconnects 334b.

The device 306 may be configured to be electrically coupled to the integrated device 303a and/or the integrated device 303b. In some implementations, the device 306 may be configured to be electrically coupled to the integrated device 303a and/or the integrated device 303b through the plurality of interconnects 523 of the package substrate 502. In some implementations, the device 306 may be directly coupled to the integrated device 303a through a plurality of pillar interconnects 331a and a plurality of solder interconnects 334a. In some implementations, the device 306 may be directly coupled to the integrated device 303b through a plurality of pillar interconnects 331b and a plurality of solder interconnects 334b.

The device 306 may include a silicon bridge, as described in the passive device 100 and/or the active device 200. The device 306 may include a bridge substrate (e.g., silicon substrate, silicon bridge substrate) and a plurality of bridge interconnects. The device 306 may also include at least one bridge dielectric layer. The device 306 may include a plurality of post interconnects 365. The device 306 may include a capacitor, as described in the passive device 100 and/or the active device 200. The device 306 may include a memory, as described in the active device 200. In some implementations, there may be more than one devices (e.g., one or more devices 306). In such instances, the one or more devices 306 may represent different combinations of the passive device 100 and/or the active device 200. For example, when there are two devices 306, one device may represent a passive device 100 and another device may represent an active device 200. In another example, when there are two devices 306, both devices may each represent a passive device 100. In yet another example, when there are two devices 306, both devices may each represent an active device 200.

In some implementations, the integrated device 303a may be configured to be electrically coupled to a capacitor (e.g., 103a) from the device 306, and the integrated device 303b may be configured to be electrically coupled to another capacitor (e.g., 103b) from the device 306. In some implementations, the integrated device 303a may be configured to be electrically coupled to a memory (e.g., 201) from the device 306, and the integrated device 303b may be configured to be electrically coupled to a memory (e.g., 201) from the device 306.

An encapsulation layer 309 may be located over the package substrate 502. The package substrate 502 may be coupled to the integrated device 303a, the integrated device 303b and the encapsulation layer 309. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process.

A metallization portion (e.g., 320, 340, 420, 440) may include a redistribution portion. A plurality of metallization interconnects (e.g., 323, 343, 423, 443) may include a plurality of redistribution interconnects. A redistribution interconnect may include portions that have a U-shape or V-shape. The terms “U-shape” and “V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect). The above description of a metallization portion may apply to other metallization portions described in the disclosure.

An integrated device (e.g., 303, 305) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 303) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 300) may be implemented in a radio frequency (RF) package. The RF package may be a radio frequency front end (RFFE) package. A package (e.g., 300) may be configured to provide Wireless Fidelity (WiFi) communication and/or cellular communication (e.g., 2G, 3G, 4G, 5G, 6G). The packages (e.g., 300) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating an Active Device

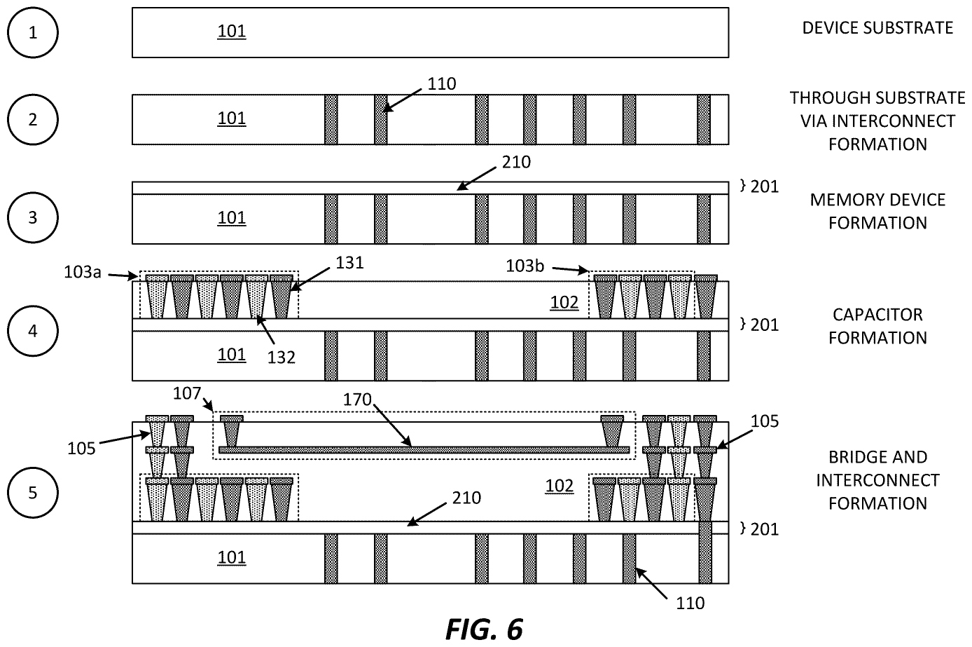

In some implementations, fabricating an active device includes several processes. FIG. 6 illustrates an exemplary sequence for providing or fabricating an active device. In some implementations, the sequence of FIG. 6 may be used to provide or fabricate the active device 200 of FIG. 2. However, the process of FIG. 6 may be used to fabricate other active devices described in the disclosure.

It should be noted that the sequence of FIG. 6 may combine one or more stages in order to simplify and/or clarify the sequence for providing or fabricating a passive device with trench capacitors. In some implementations, the order of the processes may be changed or modified. In some implementations, one or more of processes may be replaced or substituted without departing from the scope of the disclosure.

Stage 1 illustrates a state after a substrate 101 is provided. The substrate 101 may be an active device substrate. The substrate 101 may include silicon (Si).

Stage 2 illustrates a state after a plurality of through substrate via interconnects 110 are formed in the substrate 101. A plurality of cavities may be formed in the substrate 101 through a laser process and then a plating process may be used to form the plurality of through substrate via interconnects 110 in the cavities of the substrate 101.

Stage 3 illustrates a state after a memory 201 is formed in and/or on the substrate 101. The memory 201 may include a plurality of logic cells and/or transistors. A front end of line (FEOL) process may be used to form the memory 201. Forming the memory 201 may include forming a plurality of logic cells and/or a plurality of transistors in and/or on the substrate 101.

Stage 4 illustrates a state after a plurality of capacitors 103 are formed. The plurality of capacitors 103 may include a capacitor 103a and a capacitor 103b. Forming the plurality of capacitors 103 may include forming a plurality of capacitor interconnects 131 and a plurality of capacitor interconnects 132 in a dielectric layer 102. A back end of line (BEOL) process may be used to form the plurality of capacitor interconnects 131 and the plurality of capacitor interconnects 132.

Stage 5 illustrates a state after additional dielectric layer are provided, a plurality of interconnects 105 and a bridge 107 are formed. A back end of line (BEOL) process may be used to form the plurality of interconnects 105 and the bridge 107.

### Exemplary Sequence for Fabricating a Passive Device

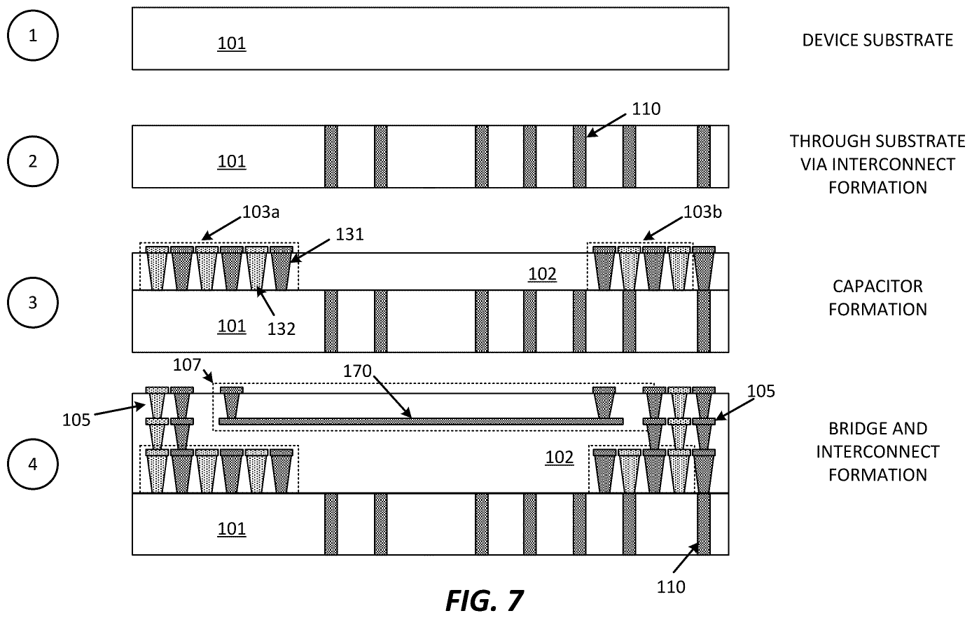

In some implementations, fabricating an passive device includes several processes. FIG. 7 illustrates an exemplary sequence for providing or fabricating a passive device. In some implementations, the sequence of FIG. 7 may be used to provide or fabricate the passive device 100 of FIG. 1. However, the process of FIG. 7 may be used to fabricate other passive devices described in the disclosure.

It should be noted that the sequence of FIG. 7 may combine one or more stages in order to simplify and/or clarify the sequence for providing or fabricating a passive device with trench capacitors. In some implementations, the order of the processes may be changed or modified. In some implementations, one or more of processes may be replaced or substituted without departing from the scope of the disclosure.

Stage 1 illustrates a state after a substrate 101 is provided. The substrate 101 may be a passive device substrate. The substrate 101 may include silicon (Si).

Stage 2 illustrates a state after a plurality of through substrate via interconnects 110 are formed in the substrate 101. A plurality of cavities may be formed in the substrate 101 through a laser process and then a plating process may be used to form the plurality of through substrate via interconnects 110 in the cavities of the substrate 101.

Stage 3 illustrates a state after a plurality of capacitors 103 are formed. The plurality of capacitors 103 may include a capacitor 103a and a capacitor 103b. Forming the plurality of capacitors 103 may include forming a plurality of capacitor interconnects 131 and a plurality of capacitor interconnects 132 in a dielectric layer 102. A back end of line (BEOL) process may be used to form the plurality of capacitor interconnects 131 and the plurality of capacitor interconnects 132.

Stage 4 illustrates a state after additional dielectric layer are provided, a plurality of interconnects 105 and a bridge 107 are formed. A back end of line (BEOL) process may be used to form the plurality of interconnects 105 and the bridge 107.

### Exemplary Sequence for Fabricating a Package Comprising a Passive Device And/or an Active Device

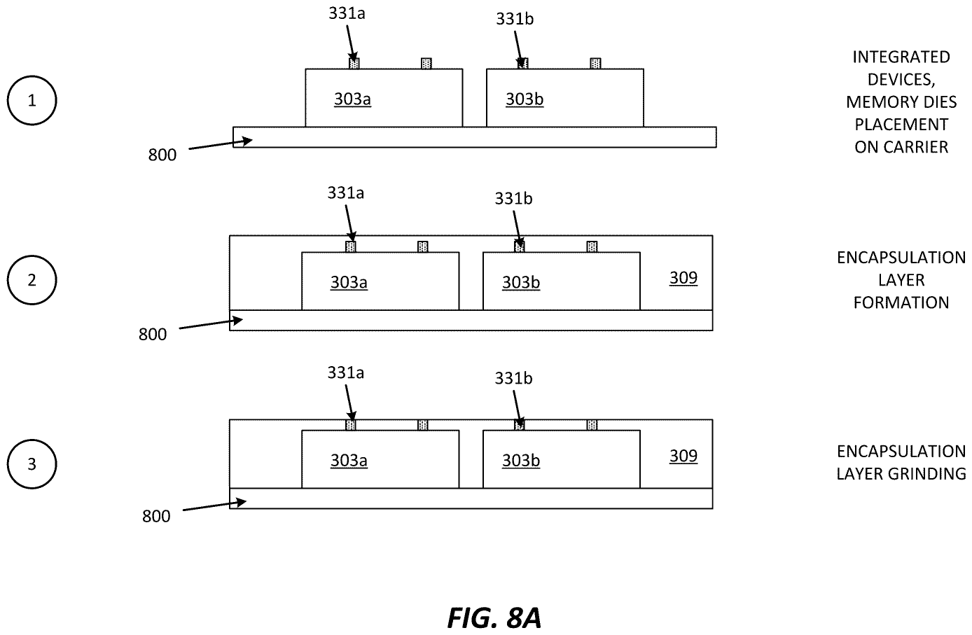

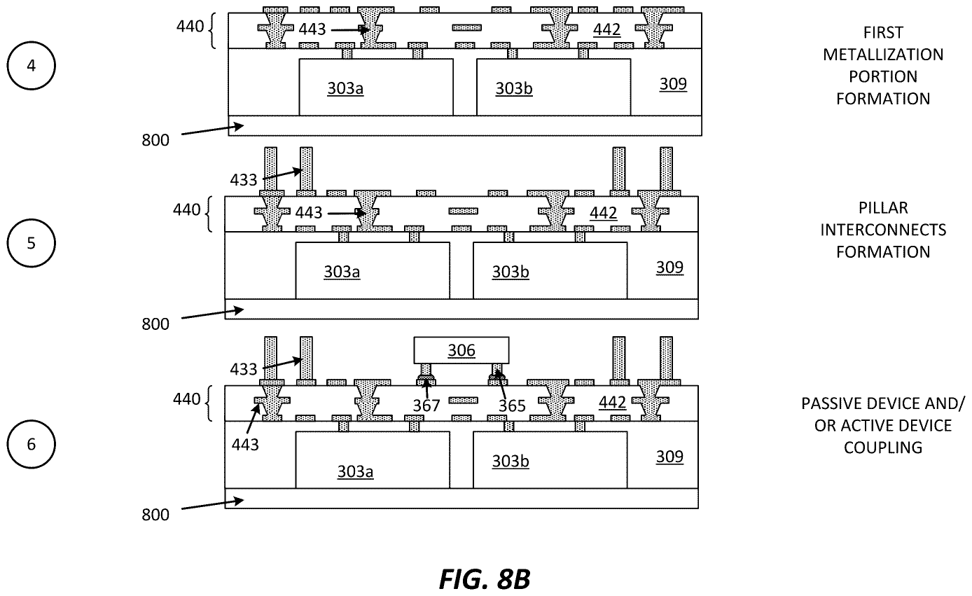

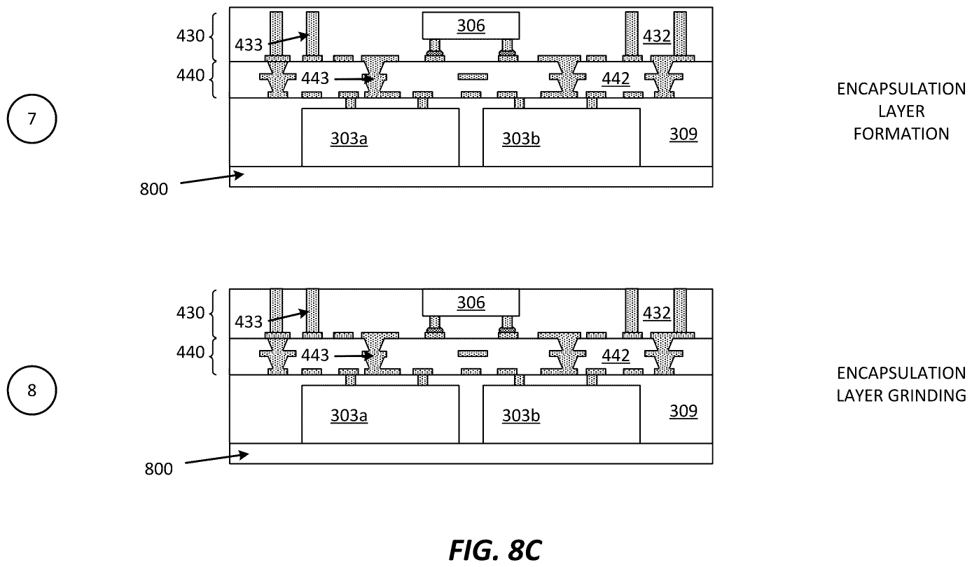

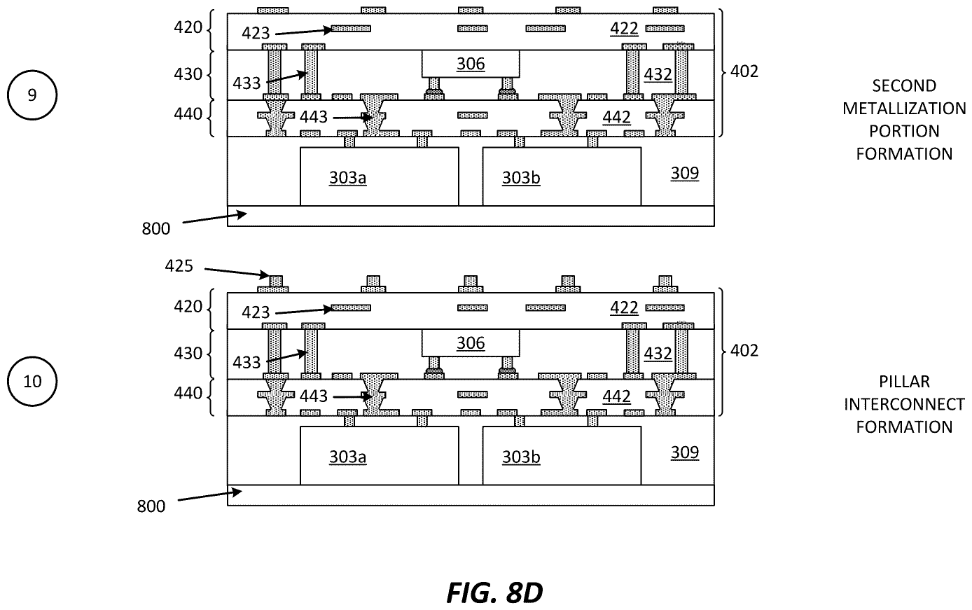

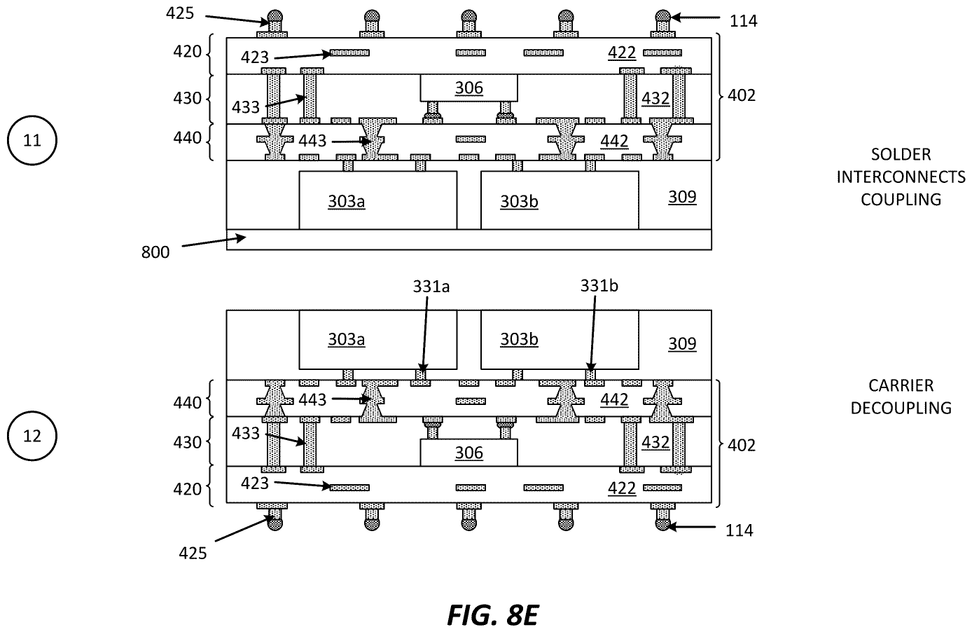

In some implementations, fabricating a package includes several processes. FIGS. 8A-8E illustrate an exemplary sequence for providing or fabricating a package. In some implementations, the sequence of FIGS. 8A-8E may be used to provide or fabricate the package 400. However, the process of FIGS. 8A-8E may be used to fabricate any of the packages described in the disclosure.

It should be noted that the sequence of FIGS. 8A-8E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1 of FIG. 8A, illustrates a state after a carrier 800 and a plurality of integrated devices is placed on the carrier 800. The plurality of integrated devices may be coupled to the carrier 800 through one or more adhesives. A back side of the integrated device 303a is placed and/or coupled to the carrier 800. The integrated device 303a may include a plurality of pillar interconnects 331a. A back side of the integrated device 303b is placed and/or coupled to the carrier 800. The integrated device 303b may include a plurality of pillar interconnects 331b.

Stage 2 of FIG. 8A, illustrates a state after an encapsulation layer 309 is formed and coupled to the carrier 800, the integrated device 303a, and the integrated device 303b. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may be over molded. The encapsulation layer 309 may at least partially encapsulate the integrated device 303a, the integrated device 303b, the plurality of pillar interconnects 331a and/or the plurality of pillar interconnects 331b.

Stage 3 of FIG. 8A, illustrates a state after portions of the encapsulation layer 309 are removed. A grinding process may be used remove portions of the encapsulation layer 309. In some implementations, portions of pillar interconnects (e.g., 331a, 331b) and/or part of the integrated device 303a and/or the integrated device 303b may also be removed.

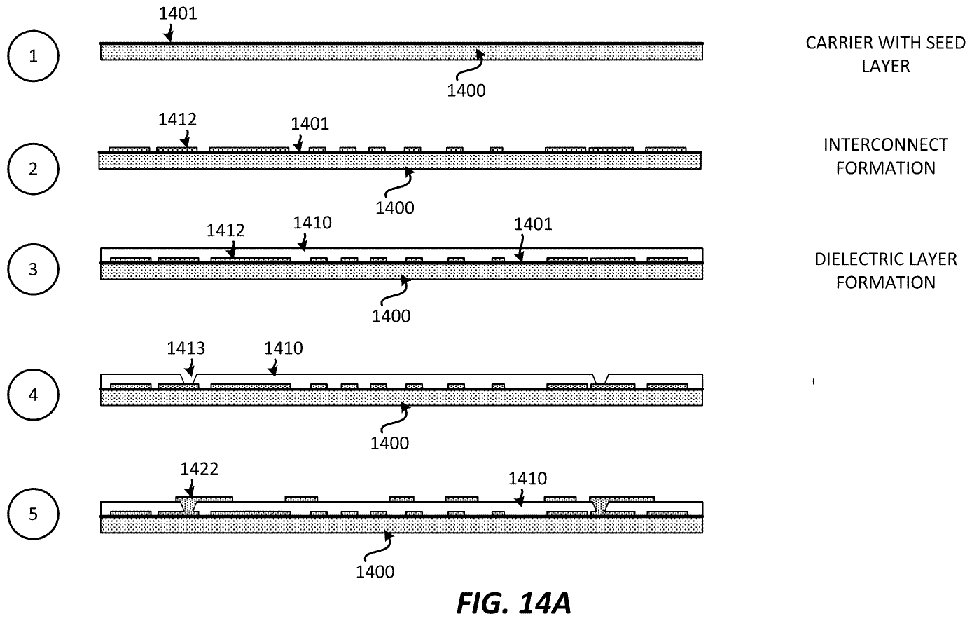

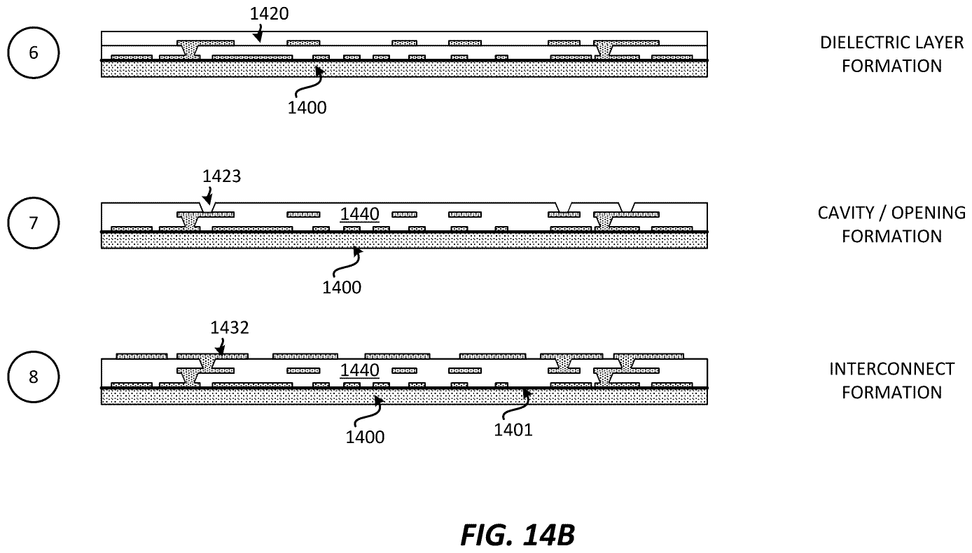

Stage 4 of FIG. 8B, illustrates a state after a metallization portion 440 is formed and coupled to the encapsulation layer 309. The metallization portion 440 includes at least one dielectric layer 442 and a plurality of metallization interconnects 443. In some implementations, the metallization portion 440 may be a first metallization portion. In some implementations, the at least one dielectric layer 442 may be an at least first dielectric layer. In some implementations, the plurality of metallization interconnects 443 may be a first plurality of metallization interconnects. In some implementations, a deposition process, a lamination process, an etching process (e.g., photo etching process), a laser process, an exposure process, a development process, a lithography process, a plating process, and/or a strip process may be used to form the metallization portion 440 comprising the at least one dielectric layer 442 and the plurality of metallization interconnects 443. An example of forming a metallization portion is illustrated and described below in at least FIGS. 14A-14B.

Stage 5 of FIG. 8B, illustrates a state after a plurality of post interconnects 433 are formed and coupled to the metallization portion 440. The plurality of post interconnects 433 may be coupled to the plurality of metallization interconnects 443. A lithography process, a plating process, a strip process and/or an etching process may be used to form the plurality of post interconnects 433.

Stage 6 of FIG. 8B, illustrates a state after a device 306 is coupled to the metallization portion 440. A front side of the device 306 is coupled to the metallization portion 440 through a plurality of post interconnects 365 and/or a plurality of solder interconnects 367. A bridge may include a front side and a back side. The back side of a bridge (e.g., silicon bridge) may be a side that includes a bridge substrate (e.g., silicon bridge substrate). The front side of a bridge may be a side that includes a bridge interconnect and/or a bridge dielectric layer. A solder reflow process may be used to couple the device 306 to the metallization portion 440.

Stage 7 of FIG. 8C, illustrates a state after an encapsulation layer 432 is formed and coupled to the metallization portion 440. The encapsulation layer 432 may be a second encapsulation layer. The encapsulation layer 432 may include a mold, a resin, an epoxy and/or a filler. The encapsulation layer 432 may be a means for encapsulation. The encapsulation layer 432 may be provided by using a compression and transfer molding process, a sheet molding process, or a liquid molding process. The encapsulation layer 432 may at least partially encapsulate the plurality of post interconnects 433, the device 306. The encapsulation layer 432 may be over molded. The encapsulation layer 432 may at least partially encapsulate the plurality of post interconnects 365, the plurality of interconnects 448a (e.g., post interconnects), the plurality of interconnects 448b (e.g., post interconnects), the plurality of solder interconnects 367, the plurality of solder interconnects 447a and/or, the plurality of solder interconnects 447b.

Stage 8 of FIG. 8C, illustrates a state a portion of the encapsulation layer 432 is removed. The encapsulation layer 432 may be grinded to form an encapsulation layer 432 with a planar surface. Portions of the plurality of post interconnects 433 and/or other post interconnects (e.g., 448a, 448b) may also be removed. Stage 8 may illustrate an encapsulated portion 430 that includes an encapsulation layer 432, a plurality of post interconnects 433, at least one bridge and at least one passive device. Stage 8 of FIG. 8C, illustrates an encapsulated portion 430 that is coupled to the metallization portion 440.

Stage 9 of FIG. 8D, illustrates a state after a metallization portion 420 is formed over and coupled to the encapsulated portion 430. The metallization portion 420 may be formed over the encapsulation layer 432. The metallization portion 420 includes at least one dielectric layer 422 and a plurality of metallization interconnects 423. In some implementations, the metallization portion 420 may be a second metallization portion. In some implementations, the at least one dielectric layer 422 may be an at least second dielectric layer. In some implementations, the plurality of metallization interconnects 423 may be a second plurality of metallization interconnects. The plurality of metallization interconnects 423 may be coupled to and touch, the plurality of post interconnects 433 and/or other post interconnects (e.g., 448a, 448b) in the encapsulation layer 432. In some implementations, a deposition process, a lamination process, an etching process (e.g., photo etching process), a laser process, an exposure process, a development process, a lithography process, a plating process, and/or a strip process may be used to form the metallization portion 420 comprising the at least one dielectric layer 422 and the plurality of metallization interconnects 423. Stage 9 may illustrate a package interposer 402 that includes the metallization portion 420, the encapsulated portion 430 and the metallization portion 440. The encapsulated portion 430 may be located between the metallization portion 420 and the metallization portion 440. An example of forming a metallization portion is illustrated and described below in at least FIGS. 14A-14B.

Stage 10 of FIG. 8D, illustrates a state after a plurality of pillar interconnects 425 are formed and coupled to the metallization portion 420. The plurality of pillar interconnects 425 may be coupled to the plurality of metallization interconnects 423. A lithography process, a plating process, a strip process and/or an etching process may be used to form the plurality of pillar interconnects 425. The plurality of pillar interconnects 425 may be optional. In some implementations, the metallization portion 420 may be optional. In such instances, the plurality of pillar interconnects 425 may be formed and coupled to the plurality of post interconnects 433.

Stage 11 of FIG. 8E, illustrates a state after a plurality of solder interconnects 114 are coupled to the plurality of pillar interconnects 425. A solder reflow process may be used to couple the plurality of pillar interconnects 425. In some implementations, the plurality of solder interconnects 114 may be coupled to the plurality of metallization interconnects 423.

Stage 12 of FIG. 8E, illustrates a state after the package interposer 402 is decoupled from the carrier 800. The package interposer 402 may be detached from the carrier 800. Stage 12 of FIG. 8E may illustrate a package 400.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Package Comprising a Passive Device and/or an Active Device

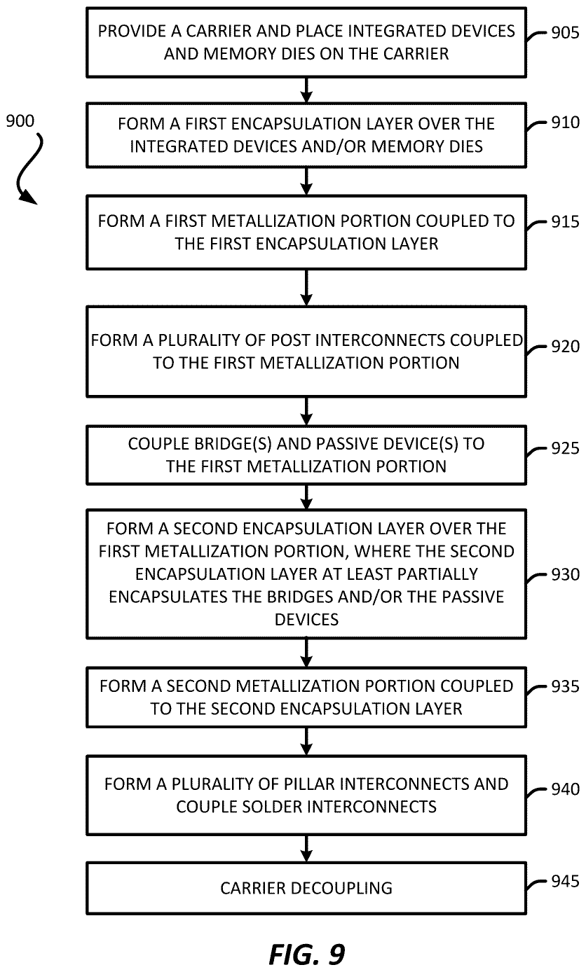

In some implementations, fabricating a package includes several processes. FIG. 9 illustrates an exemplary flow diagram of a method 900 for providing or fabricating a package. In some implementations, the method 900 of FIG. 9 may be used to provide or fabricate the package 400 described in the disclosure. However, the method 900 may be used to provide or fabricate any of the packages described in the disclosure.

It should be noted that the method 900 of FIG. 9 may combine one or more processes in order to simplify and/or clarify the method for providing or fabricating a package. In some implementations, the order of the processes may be changed or modified.

The method provides (at 905) a carrier and places (at 905) integrated devices on the carrier. Stage 1 of FIG. 8A, illustrates and describes an example of a state after a carrier 800 and a plurality of integrated devices is placed on the carrier 800. The plurality of integrated devices may be coupled to the carrier 800 through one or more adhesives. A back side of the integrated device 303a is placed and/or coupled to the carrier 800. The integrated device 303a may include a plurality of pillar interconnects 331a. A back side of the integrated device 303b is placed and/or coupled to the carrier 800. The integrated device 303b may include a plurality of pillar interconnects 331b.

The method forms (at 910) a first encapsulation layer over the integrated devices and/or the memory dies. Stage 2 of FIG. 8A, illustrates and describes an example of a state after an encapsulation layer 309 is formed and coupled to the carrier 800, the integrated device 303a, and the integrated device 303b. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may be over molded. The encapsulation layer 309 may at least partially encapsulate the integrated device 303a, the integrated device 303b, the plurality of pillar interconnects 331a and/or the plurality of pillar interconnects 331b. Forming an encapsulation layer may include removing portions of the encapsulation layer. Stage 3 of FIG. 8A, illustrates and describes an example of a state after portions of the encapsulation layer 309 are removed. A grinding process may be used remove portions of the encapsulation layer 309. In some implementations, portions of pillar interconnects (e.g., 331a, 331b) and/or part of the integrated device 303a and/or the integrated device 303b may also be removed.

The method forms (at 915) a first metallization portion coupled to the encapsulation layer. Stage 4 of FIG. 8B, illustrates and describes an example of a state after a metallization portion 440 is formed and coupled to the encapsulation layer 309. The metallization portion 440 includes at least one dielectric layer 442 and a plurality of metallization interconnects 443. In some implementations, the metallization portion 440 may be a first metallization portion. In some implementations, the at least one dielectric layer 442 may be an at least first dielectric layer. In some implementations, the plurality of metallization interconnects 443 may be a first plurality of metallization interconnects. In some implementations, a deposition process, a lamination process, an etching process (e.g., photo etching process), a laser process, an exposure process, a development process, a lithography process, a plating process, and/or a strip process may be used to form the metallization portion 440 comprising the at least one dielectric layer 442 and the plurality of metallization interconnects 443. An example of forming a metallization portion is illustrated and described below in at least FIGS. 14A-14B.

The method forms (at 920) a plurality of post interconnects that are coupled to the first metallization portion. Stage 5 of FIG. 8B, illustrates and describes an example of a state after a plurality of post interconnects 433 are formed and coupled to the metallization portion 440. The plurality of post interconnects 433 may be coupled to the plurality of metallization interconnects 443. A lithography process, a plating process, a strip process and/or an etching process may be used to form the plurality of post interconnects 433.

The method couples (at 925) a bridge and passive devices to the first metallization portion. Stage 6 of FIG. 8B, illustrates and describes an example of a state after a device 306 is coupled to the metallization portion 440. A front side of the device 306 is coupled to the metallization portion 440 through a plurality of post interconnects 365 and/or a plurality of solder interconnects 367. A bridge may include a front side and a back side. The back side of a bridge (e.g., silicon bridge) may be a side that includes a bridge substrate (e.g., silicon bridge substrate). The front side of a bridge may be a side that includes a bridge interconnect and/or a bridge dielectric layer. A solder reflow process may be used to couple the device 306 to the metallization portion 440.

The method forms (at 930) a second encapsulation layer over the first metallization portion. Stage 7 of FIG. 8C, illustrates and describes an example of a state after an encapsulation layer 432 is formed and coupled to the metallization portion 440. The encapsulation layer 432 may be a second encapsulation layer. The encapsulation layer 432 may include a mold, a resin, an epoxy and/or a filler. The encapsulation layer 432 may be a means for encapsulation. The encapsulation layer 432 may be provided by using a compression and transfer molding process, a sheet molding process, or a liquid molding process. The encapsulation layer 432 may at least partially encapsulate the plurality of post interconnects 433, the device 306. The encapsulation layer 432 may be over molded. The encapsulation layer 432 may at least partially encapsulate the plurality of post interconnects 365, the plurality of interconnects 448a (e.g., post interconnects), the plurality of interconnects 448b (e.g., post interconnects), the plurality of solder interconnects 367, the plurality of solder interconnects 447a and/or, the plurality of solder interconnects 447b. Forming the encapsulation layer may include removing portions of an encapsulation layer. Stage 8 of FIG. 8C, illustrates and describes an example of a state a portion of the encapsulation layer 432 is removed. The encapsulation layer 432 may be grinded to form an encapsulation layer 432 with a planar surface. Portions of the plurality of post interconnects 433 and/or other post interconnects (e.g., 448a, 448b) may also be removed. Stage 8 may illustrate an encapsulated portion 430 that includes an encapsulation layer 432, a plurality of post interconnects 433, at least one bridge and at least one passive device. Stage 8 of FIG. 8C, illustrates an encapsulated portion 430 that is coupled to the metallization portion 440.

The method forms (at 935) a second metallization portion that is coupled to the encapsulated portion. Stage 9 of FIG. 8D, illustrates and describes an example of a state after a metallization portion 420 is formed over and coupled to the encapsulated portion 430. The metallization portion 420 may be formed over the encapsulation layer 432. The metallization portion 420 includes at least one dielectric layer 422 and a plurality of metallization interconnects 423. In some implementations, the metallization portion 420 may be a second metallization portion. In some implementations, the at least one dielectric layer 422 may be an at least second dielectric layer. In some implementations, the plurality of metallization interconnects 423 may be a second plurality of metallization interconnects. The plurality of metallization interconnects 423 may be coupled to and touch, the plurality of post interconnects 433 and/or other post interconnects (e.g., 448a, 448b) in the encapsulation layer 432. In some implementations, a deposition process, a lamination process, an etching process (e.g., photo etching process), a laser process, an exposure process, a development process, a lithography process, a plating process, and/or a strip process may be used to form the metallization portion 420 comprising the at least one dielectric layer 422 and the plurality of metallization interconnects 423. Stage 9 may illustrate a package interposer 402 that includes the metallization portion 420, the encapsulated portion 430 and the metallization portion 440. The encapsulated portion 430 may be located between the metallization portion 420 and the metallization portion 440. An example of forming a metallization portion is illustrated and described below in at least FIGS. 14A-14B.

The method forms (at 940) a plurality of pillar interconnects and/or a plurality of solder interconnects. Stage 10 of FIG. 8D, illustrates and describes an example of a state after a plurality of pillar interconnects 425 are formed and coupled to the metallization portion 420. The plurality of pillar interconnects 425 may be coupled to the plurality of metallization interconnects 423. A lithography process, a plating process, a strip process and/or an etching process may be used to form the plurality of pillar interconnects 425. The plurality of pillar interconnects 425 may be optional. In some implementations, the metallization portion 420 may be optional. In such instances, the plurality of pillar interconnects 425 may be formed and coupled to the plurality of post interconnects 433. Stage 11 of FIG. 8E, illustrates and describes an example of a state after a plurality of solder interconnects 114 are coupled to the plurality of pillar interconnects 425. A solder reflow process may be used to couple the plurality of pillar interconnects 425. In some implementations, the plurality of solder interconnects 114 may be coupled to the plurality of metallization interconnects 423.

The method decouples (at 945) a carrier from the package interposer. Stage 12 of FIG. 8E, illustrates and describes an example of a state after the package interposer 402 is decoupled from the carrier 800. The package interposer 402 may be detached from the carrier 800. Stage 12 of FIG. 8E may illustrate a package 400.

### Exemplary Sequence for Fabricating a Package Comprising a Passive Device and/or an Active Device

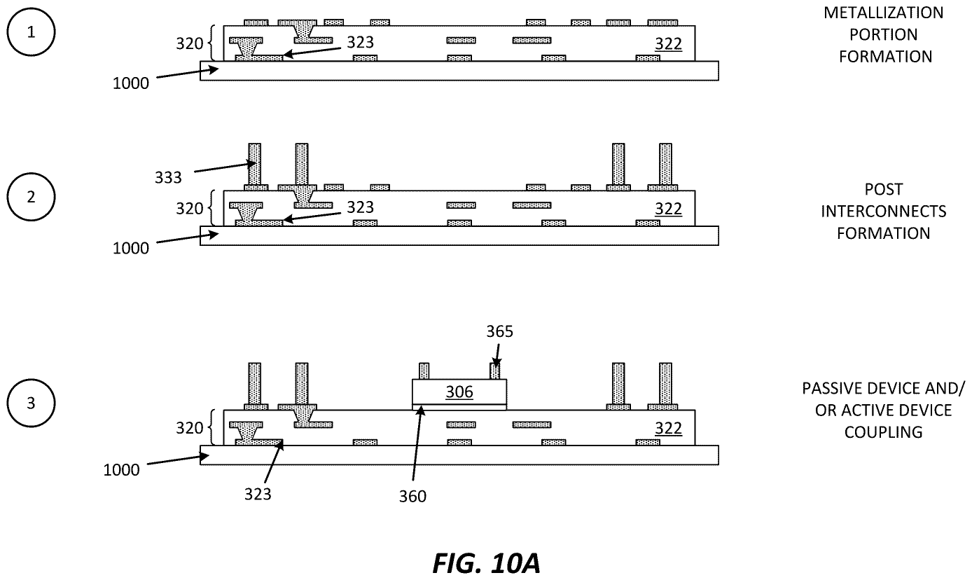

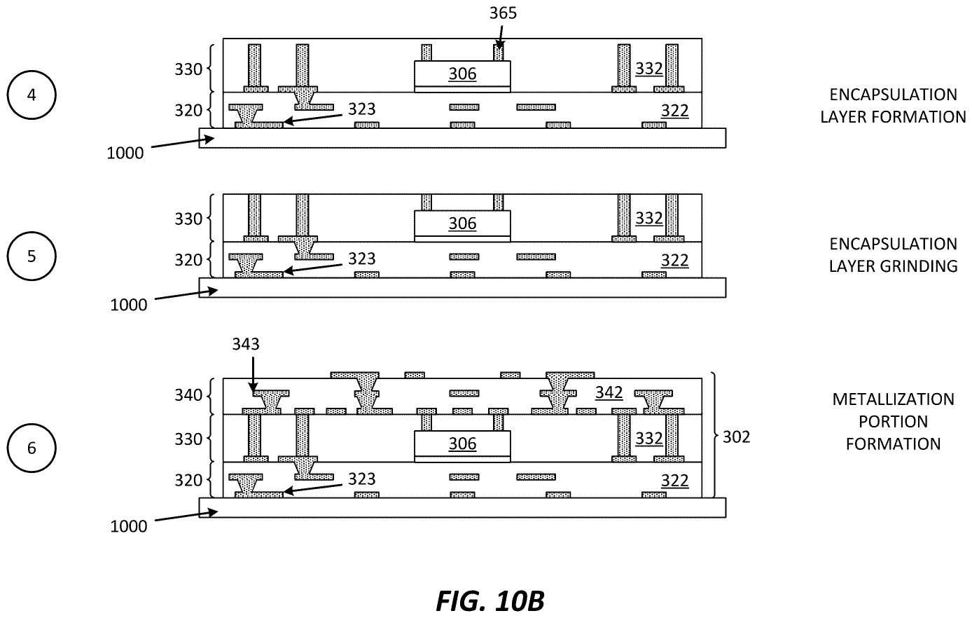

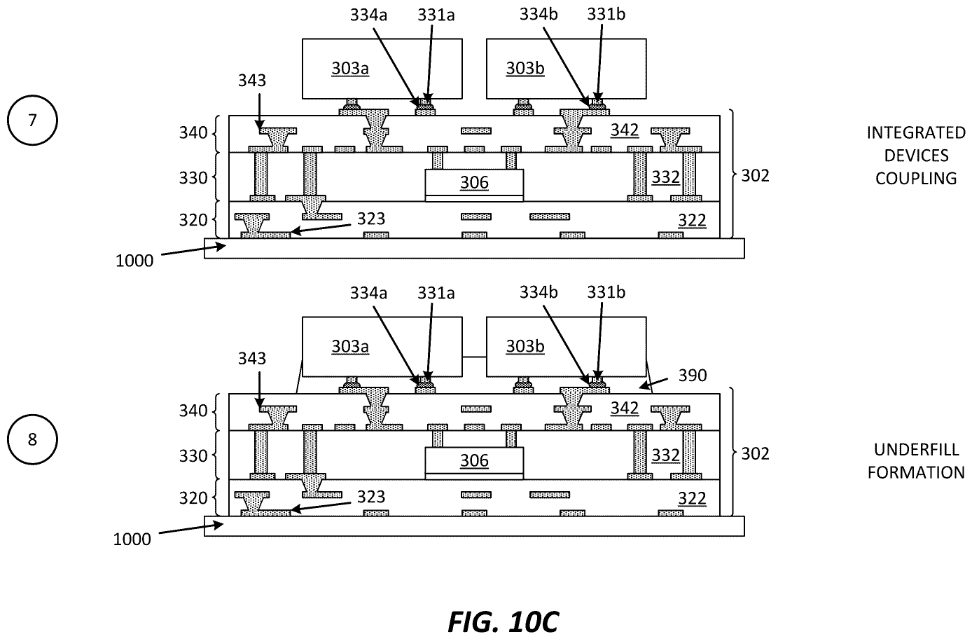

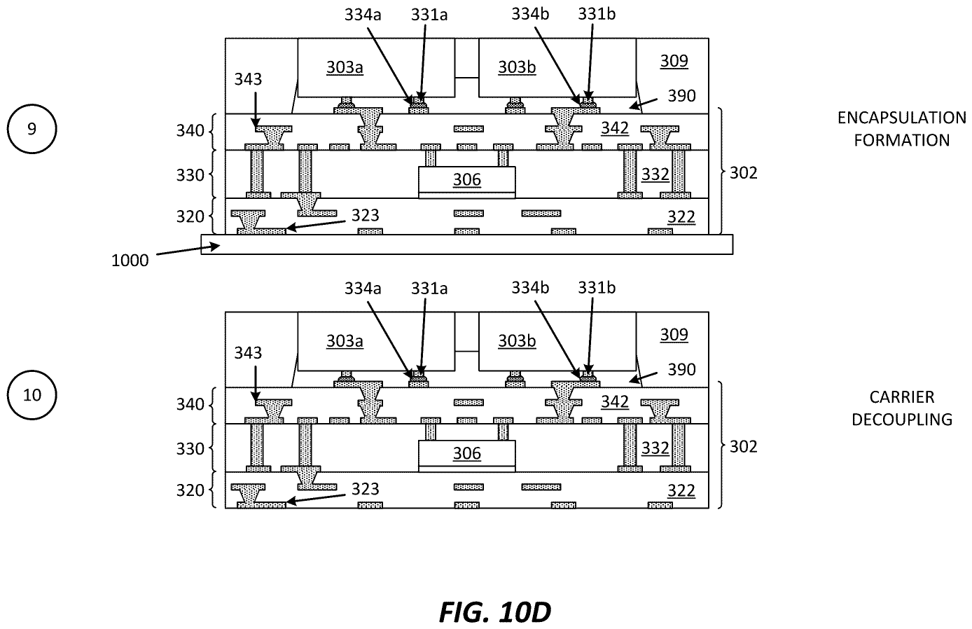

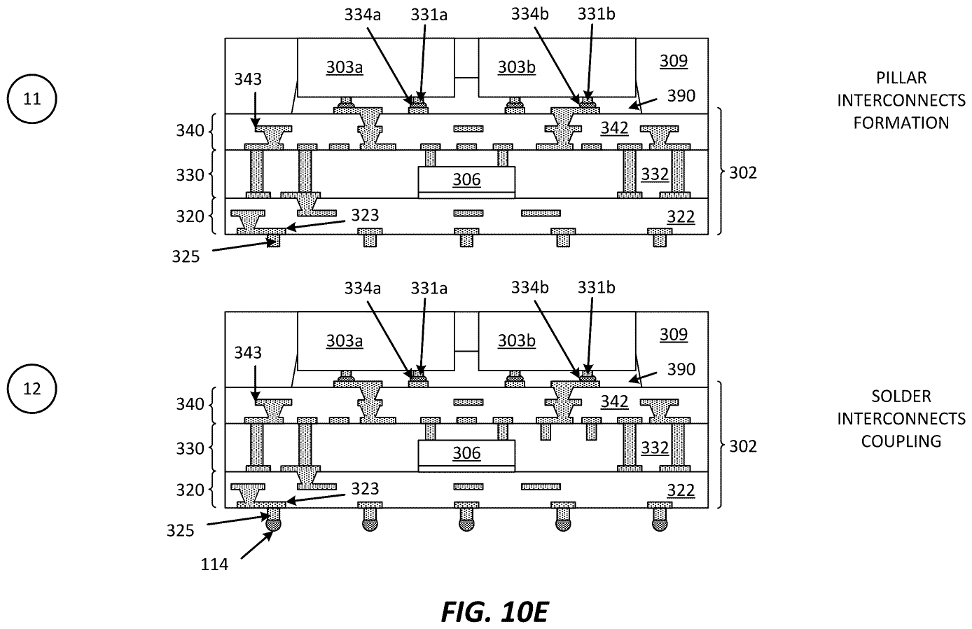

In some implementations, fabricating a package includes several processes. FIGS. 10A-10E illustrate an exemplary sequence for providing or fabricating a package. In some implementations, the sequence of FIGS. 10A-10E may be used to provide or fabricate the package 300. However, the process of FIGS. 10A-10E may be used to fabricate any of the packages described in the disclosure.

It should be noted that the sequence of FIGS. 10A-10E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1 of FIG. 10A, illustrates a state after a carrier 1000 and a metallization portion 320 is formed on the carrier 1000. The carrier 1000 may include a glass carrier. The metallization portion 320 includes at least one dielectric layer 322 and a plurality of metallization interconnects 323. In some implementations, the metallization portion 320 may be a first metallization portion. In some implementations, the at least one dielectric layer 322 may be an at least first dielectric layer. In some implementations, the plurality of metallization interconnects 323 may be a first plurality of metallization interconnects. In some implementations, a deposition process, a lamination process, an etching process (e.g., photo etching process), a laser process, an exposure process, a development process, a lithography process, a plating process, and/or a strip process may be used to form the metallization portion 320 comprising the at least one dielectric layer 322 and the plurality of metallization interconnects 323. An example of forming a metallization portion is illustrated and described below in at least FIGS. 14A-14B.

Stage 2 of FIG. 10A, illustrates a state after a plurality of post interconnects 333 are formed and coupled to the metallization portion 320. The plurality of post interconnects 333 may be coupled to the plurality of metallization interconnects 323. A lithography process, a plating process, a strip process and/or an etching process may be used to form the plurality of post interconnects 333. In some implementations, the metallization portion 320 may be optional. In such instances, the plurality of post interconnects 333 may be formed and coupled to the carrier 1000.

Stage 3 of FIG. 10A, illustrates a state after a device 306 is coupled to the metallization portion 320. A back side of the device 306 is coupled to the metallization portion 320 through an adhesive 360. The device 306 may include the plurality of post interconnects 365. The back side of a bridge (e.g., silicon bridge) may be a side that includes a bridge substrate (e.g., silicon bridge substrate). The front side of a bridge may be a side that includes a bridge interconnect and/or a bridge dielectric layer.

Stage 4 of FIG. 10B, illustrates a state after an encapsulation layer 332 is formed and coupled to the metallization portion 320. The encapsulation layer 332 may be a first encapsulation layer. The encapsulation layer 332 may include a mold, a resin, an epoxy and/or a filler. The encapsulation layer 332 may be a means for encapsulation. The encapsulation layer 332 may be provided by using a compression and transfer molding process, a sheet molding process, or a liquid molding process. The encapsulation layer 332 may at least partially encapsulate the plurality of post interconnects 333, the device 306, the plurality of post interconnects 365, the plurality of post interconnects 345a and/or the plurality of post interconnects 345b. The encapsulation layer 332 may be over molded and grinded.

Stage 5 of FIG. 10B, illustrates a state a portion of the encapsulation layer 332 is removed. The encapsulation layer 332 may be grinded to form an encapsulation layer 332 with a planar surface. Portions of the plurality of post interconnects 333 and/or other post interconnects (e.g., 345a, 345b, 365) may also be removed. Stage 5 of FIG. 10B, may illustrate the encapsulated portion 330 that is coupled to the metallization portion 320.

Stage 6 of FIG. 10B, illustrates a state after a metallization portion 340 is formed over and coupled to the encapsulated portion 330. The metallization portion 340 may be formed over the encapsulation layer 332. The metallization portion 340 includes at least one dielectric layer 342 and a plurality of metallization interconnects 343. In some implementations, the metallization portion 340 may be a second metallization portion. In some implementations, the at least one dielectric layer 342 may be an at least second dielectric layer. In some implementations, the plurality of metallization interconnects 343 may be a second plurality of metallization interconnects. The plurality of metallization interconnects 343 may be coupled to the plurality of post interconnects 333 and/or other post interconnects (e.g., 345a, 345b, 365) in the encapsulation layer 332. In some implementations, a deposition process, a lamination process, an etching process (e.g., photo etching process), a laser process, an exposure process, a development process, a lithography process, a plating process, and/or a strip process may be used to form the metallization portion 340 comprising the at least one dielectric layer 342 and the plurality of metallization interconnects 343. An example of forming a metallization portion is illustrated and described below in at least FIGS. 10A-10B. Stage 6 may illustrate a package interposer 302 that includes the metallization portion 320, the encapsulated portion 330 and the metallization portion 340. The encapsulated portion 330 may be located between the metallization portion 320 and the metallization portion 340.

Stage 7 of FIG. 10C, illustrates a state after integrated devices are coupled to the package interposer 302. The integrated device 303a is coupled to the metallization portion 340 through a plurality of pillar interconnects 331a and a plurality of solder interconnects 334a. A solder reflow process may be used to couple the integrated device 303a to the metallization portion 340. The integrated device 303b is coupled to the metallization portion 340 through a plurality of pillar interconnects 331b and a plurality of solder interconnects 334b. A solder reflow process may be used to couple the integrated device 303b to the metallization portion 340.

Stage 8 of FIG. 10C, illustrates a state after an underfill 390 is provided. The underfill 390 may be disposed on the package interposer 302. The underfill 390 may be located between (i) the metallization portion 340 and (ii) the integrated device 303a and/or the integrated device 303b. In some implementations, the underfill 390 may include a composite material comprising an epoxy polymer with filler.

Stage 9 of FIG. 10D, illustrates a state after an encapsulation layer 309 is formed and coupled to the package interposer 302. The encapsulation layer 309 is coupled to the metallization portion 340. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may include a different material and/or a different composition from the underfill 390. The encapsulation layer 309 may be over molded and a grinding process may be used to remove a portion of the encapsulation layer 309. The encapsulation layer 309 may at least partially encapsulate the integrated device 303a and/or the integrated device 303b.

Stage 10 of FIG. 10D, illustrates a state after the package interposer 302 is decoupled from the carrier 1000. The package interposer 302 may be detached from the carrier 1000.

Stage 11 of FIG. 10E, illustrates a state after a plurality of pillar interconnects 325 are formed and coupled to the metallization portion 320. The plurality of pillar interconnects 325 may be coupled to the plurality of metallization interconnects 323. A lithography process, a plating process, a strip process and/or an etching process may be used to form the plurality of pillar interconnects 325. The plurality of pillar interconnects 325 may be optional.

Stage 12 of FIG. 10E, illustrates a state after a plurality of solder interconnects 114 are coupled to the plurality of pillar interconnects 325. A solder reflow process may be used to couple the plurality of pillar interconnects 325. In some implementations, the plurality of solder interconnects 318 may be coupled to the plurality of metallization interconnects 323. Stage 12 of FIG. 10E may illustrate a package 300.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Package Comprising a Passive Device and/or an Active Device

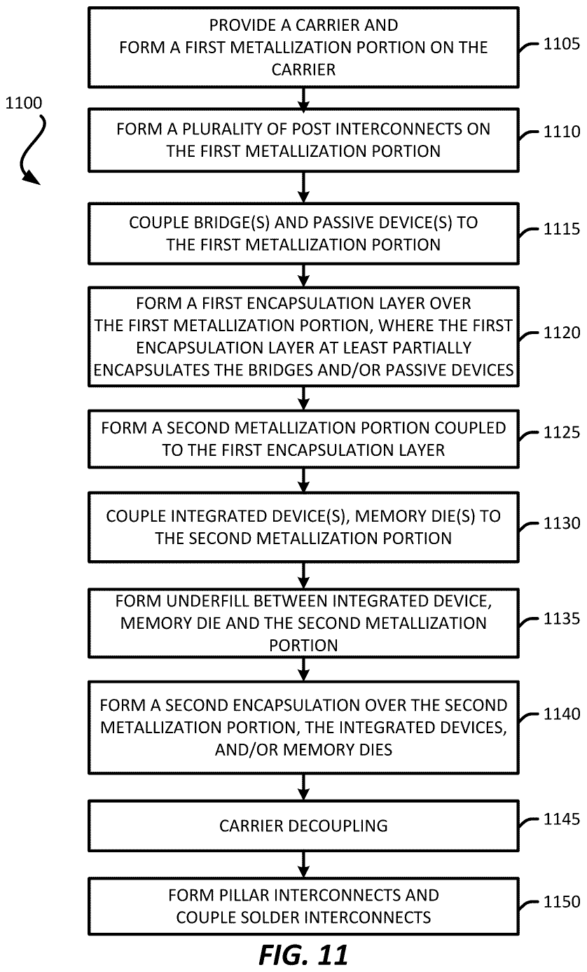

In some implementations, fabricating a package includes several processes. FIG. 11 illustrates an exemplary flow diagram of a method 1100 for providing or fabricating a package. In some implementations, the method 1100 of FIG. 11 may be used to provide or fabricate the package 300 described in the disclosure. However, the method 1100 may be used to provide or fabricate any of the packages described in the disclosure.

It should be noted that the method 1100 of FIG. 11 may combine one or more processes in order to simplify and/or clarify the method for providing or fabricating a package. In some implementations, the order of the processes may be changed or modified.

The method provides (at 1105) a carrier and forms a first metallization portion on the carrier. Stage 1 of FIG. 10A, illustrates and describes an example of a state after a carrier 1000 and a metallization portion 320 is formed on the carrier 1000. The carrier 1000 may include a glass carrier. The metallization portion 320 includes at least one dielectric layer 322 and a plurality of metallization interconnects 323. In some implementations, the metallization portion 320 may be a first metallization portion. In some implementations, the at least one dielectric layer 322 may be an at least first dielectric layer. In some implementations, the plurality of metallization interconnects 323 may be a first plurality of metallization interconnects. In some implementations, a deposition process, a lamination process, an etching process (e.g., photo etching process), a laser process, an exposure process, a development process, a lithography process, a plating process, and/or a strip process may be used to form the metallization portion 320 comprising the at least one dielectric layer 322 and the plurality of metallization interconnects 323. An example of forming a metallization portion is illustrated and described below in at least FIGS. 14A-14B.

The method forms (at 1110) a plurality of post interconnects on the first metallization portion. Stage 2 of FIG. 10A, illustrates and describes an example of a state after a plurality of post interconnects 333 are formed and coupled to the metallization portion 320. The plurality of post interconnects 333 may be coupled to the plurality of metallization interconnects 323. A lithography process, a plating process, a strip process and/or an etching process may be used to form the plurality of post interconnects 333. In some implementations, the metallization portion 320 may be optional. In such instances, the plurality of post interconnects 333 may be formed and coupled to the carrier 1000.

The method couples (at 1115) at least one bridge and/or at least passive device to the first metallization portion. Stage 3 of FIG. 10A, illustrates and describes an example of a state after a device 306 is coupled to the metallization portion 320. A back side of the device 306 is coupled to the metallization portion 320 through an adhesive 360. The device 306 may include the plurality of post interconnects 365. The back side of a bridge (e.g., silicon bridge) may be a side that includes a bridge substrate (e.g., silicon bridge substrate). The front side of a bridge may be a side that includes a bridge interconnect and/or a bridge dielectric layer.

The method forms (at 1120) a first encapsulation layer over the first metallization portion. Stage 4 of FIG. 10B, illustrates and describes an example of a state after an encapsulation layer 332 is formed and coupled to the metallization portion 320. The encapsulation layer 332 may be a first encapsulation layer. The encapsulation layer 332 may include a mold, a resin, an epoxy and/or a filler. The encapsulation layer 332 may be a means for encapsulation. The encapsulation layer 332 may be provided by using a compression and transfer molding process, a sheet molding process, or a liquid molding process. The encapsulation layer 332 may at least partially encapsulate the plurality of post interconnects 333, the device 306, the plurality of post interconnects 365, the plurality of post interconnects 345a and/or the plurality of post interconnects 345b. The encapsulation layer 332 may be over molded. Forming the first encapsulation layer may include removing portions of the first encapsulation layer. Stage 5 of FIG. 10B, illustrates and describes an example of a state a portion of the encapsulation layer 332 is removed. The encapsulation layer 332 may be grinded to form an encapsulation layer 332 with a planar surface. Portions of the plurality of post interconnects 333 and/or other post interconnects may also be removed. Stage 5 of FIG. 10B, may illustrate the encapsulated portion 330 that is coupled to the metallization portion 320.

The method forms (at 1125) a second metallization over the encapsulated portion. Stage 6 of FIG. 10B, illustrates and describes an example of a state after a metallization portion 340 is formed over and coupled to the encapsulated portion 330. The metallization portion 340 may be formed over the encapsulation layer 332. The metallization portion 340 includes at least one dielectric layer 342 and a plurality of metallization interconnects 343. In some implementations, the metallization portion 340 may be a second metallization portion. In some implementations, the at least one dielectric layer 342 may be an at least second dielectric layer. In some implementations, the plurality of metallization interconnects 343 may be a second plurality of metallization interconnects. The plurality of metallization interconnects 343 may be coupled to the plurality of post interconnects 333 and/or other post interconnects in the encapsulation layer 332. In some implementations, a deposition process, a lamination process, an etching process (e.g., photo etching process), a laser process, an exposure process, a development process, a lithography process, a plating process, and/or a strip process may be used to form the metallization portion 340 comprising the at least one dielectric layer 342 and the plurality of metallization interconnects 343. An example of forming a metallization portion is illustrated and described below in at least FIGS. 14A-14B. Stage 6 may illustrate a package interposer 302 that includes the metallization portion 320, the encapsulated portion 330 and the metallization portion 340. The encapsulated portion 330 may be located between the metallization portion 320 and the metallization portion 340.

The method places and couples (at 1130) integrated devices and/or memory dies to the second metallization portion. Stage 11 of FIG. 10C, illustrates and describes an example of a state after integrated devices are coupled to the package interposer 302. The integrated device 303a is coupled to the metallization portion 340 through a plurality of pillar interconnects 331a and a plurality of solder interconnects 334a. A solder reflow process may be used to couple the integrated device 303a to the metallization portion 340. The integrated device 303b is coupled to the metallization portion 340 through a plurality of pillar interconnects 331b and a plurality of solder interconnects 334b. A solder reflow process may be used to couple the integrated device 303b to the metallization portion 340.

The method provides and forms (at 1135) an underfill. Stage 8 of FIG. 10C, illustrates and describes an example of a state after an underfill 390 is provided. The underfill 390 may be disposed on the package interposer 302. The underfill 390 may be located between (i) the metallization portion 340 and (ii) the integrated device 303a and/or the integrated device 303b. In some implementations, the underfill 390 may include a composite material comprising an epoxy polymer with filler.

The method forms (at 1140) a second encapsulation layer. Stage 9 of FIG. 10D, illustrates and describes an example of a state after an encapsulation layer 309 is formed and coupled to the package interposer 302. The encapsulation layer 309 is coupled to the metallization portion 340. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may include a different material and/or a different composition from the underfill 390. The encapsulation layer 309 may be over molded and a grinding process may be used to remove a portion of the encapsulation layer 309. The encapsulation layer 309 may at least partially encapsulate the integrated device 303a and/or the integrated device 303b.

The method decouples (at 1145) the carrier. Stage 10 of FIG. 10D, illustrates and describes an example of a state after the package interposer 302 is decoupled from the carrier 1000. The package interposer 302 may be detached from the carrier 1000.

The method forms (at 1150) a plurality of pillar interconnects and solder interconnects. Stage 11 of FIG. 10E, illustrates and describes an example of a state after a plurality of pillar interconnects 325 are formed and coupled to the metallization portion 320. The plurality of pillar interconnects 325 may be coupled to the plurality of metallization interconnects 323. A lithography process, a plating process, a strip process and/or an etching process may be used to form the plurality of pillar interconnects 325. The plurality of pillar interconnects 325 may be optional.

Stage 12 of FIG. 10E, illustrates and describes an example of a state after a plurality of solder interconnects 114 are coupled to the plurality of pillar interconnects 325. A solder reflow process may be used to couple the plurality of pillar interconnects 325. In some implementations, the plurality of solder interconnects 318 may be coupled to the plurality of metallization interconnects 323. Stage 12 of FIG. 10E may illustrate a package 300.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Package Comprising a Passive Device and/or an Active Device

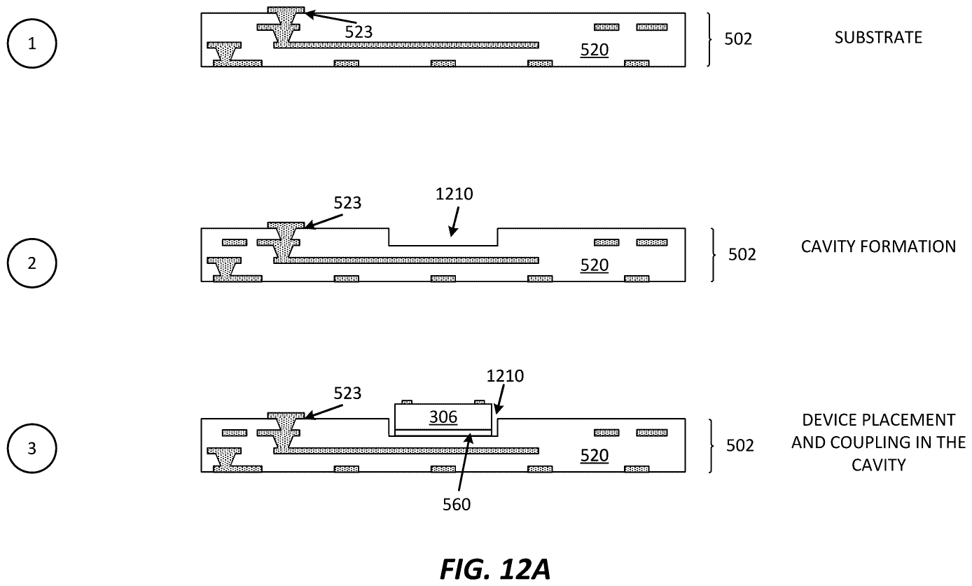

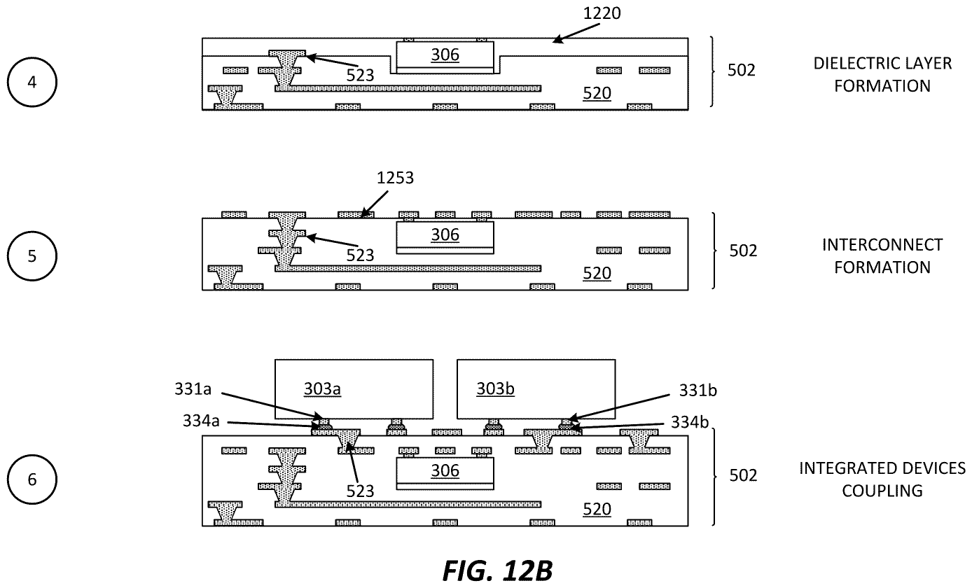

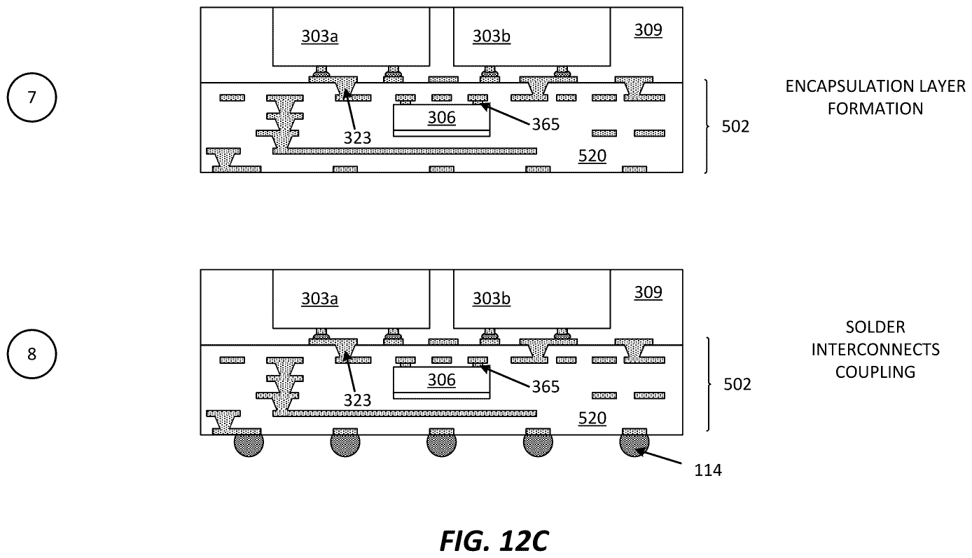

In some implementations, fabricating a package includes several processes. FIGS. 12A-12C illustrate an exemplary sequence for providing or fabricating a package. In some implementations, the sequence of FIGS. 12A-12C may be used to provide or fabricate the package 500. However, the process of FIGS. 12A-12C may be used to fabricate any of the packages described in the disclosure.

It should be noted that the sequence of FIGS. 12A-12C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1 of FIG. 12A, illustrates a state after a substrate 501 is fabricated and/or provided. The substrate 501 includes at least one dielectric layer 520 and a plurality of interconnects 523.

Stage 2 illustrates a state after a cavity 1210 is formed in the substrate 501. A laser process may be used to form the cavity 1210.

Stage 3 illustrates a state after the device 306 is placed in the cavity 1210 and coupled to the substrate 501 through an adhesive 560. The back side of the device 306 may be coupled to the substrate 501 through the adhesive 560. The device 306 may represent the passive device 100 or the active device 200.

Stage 4, as shown in FIG. 12B, illustrates a state after a dielectric layer 1220 is formed and coupled to the dielectric layer 520 and the device 306. A deposition process and/or a lamination process may be used to form the dielectric layer 1220. The dielectric layer 1220 may be formed in the cavity 1210 of the substrate 501. The dielectric layer 1220 may be considered part of the dielectric layer 520.

Stage 5 illustrates a state after a plurality of interconnects 1253 are formed in and/or on the substrate 501. A plurality of cavities may be formed in the substrate 501. A plating process may be used to form the plurality of interconnects 1253. The plurality of interconnects 1253 may be coupled to the plurality of interconnects 523. The plurality of interconnects 1253 may be considered part of the plurality of interconnects 523.

Stage 6 illustrates a state after a plurality of integrated devices are coupled to the substrate. The integrated device 303a may be coupled to the plurality of interconnects 523 of the substrate 501 through a plurality of pillar interconnects 331a and/or a plurality of solder interconnects 334a. The integrated device 303b may be coupled to the plurality of interconnects 523 of the substrate 501 through a plurality of pillar interconnects 331b and/or a plurality of solder interconnects 334b. A solder reflow process may be used to couple the plurality of integrated devices to the substrate 501.

Stage 7, as shown in FIG. 12C, illustrates a state after an encapsulation layer 309 is provided and coupled to the substrate 501. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may be over molded and grinded off (e.g., partially removed). The encapsulation layer 309 may at least partially encapsulate the integrated device 303a and the integrated device 303b.

Stage 8 illustrates a state after a plurality of solder interconnects 114 are coupled to the substrate 501. The plurality of solder interconnects 114 may be coupled to the plurality of interconnects 523 of the substrate 501.

### Exemplary Flow Diagram of a Method for Fabricating a Package Comprising a Passive Device and/or an Active Device

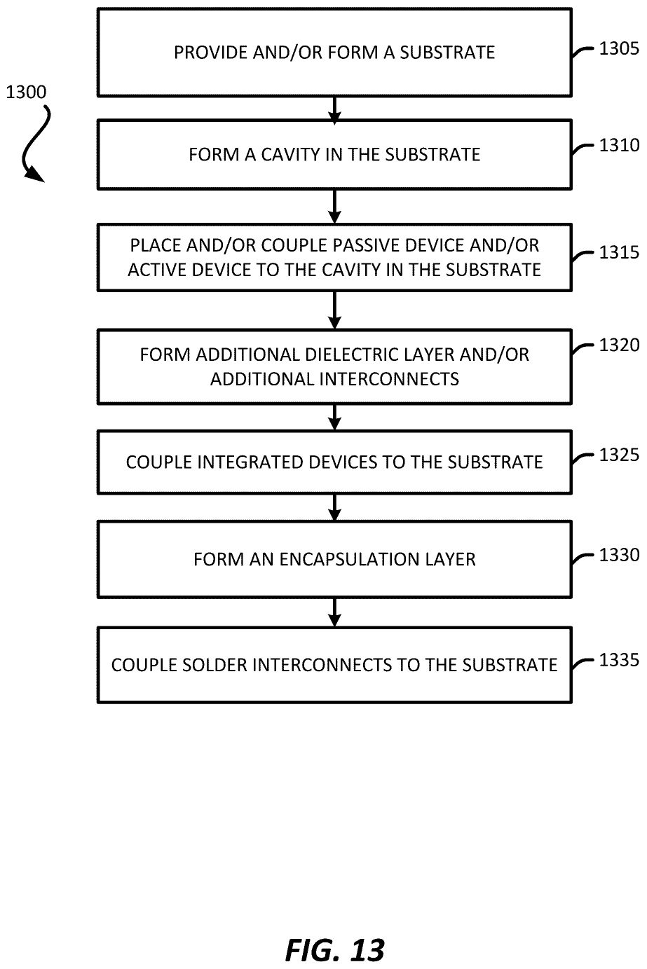

In some implementations, fabricating a package includes several processes. FIG. 13 illustrates an exemplary flow diagram of a method 1300 for providing or fabricating a package. In some implementations, the method 1300 of FIG. 13 may be used to provide or fabricate the package 300 described in the disclosure. However, the method 1300 may be used to provide or fabricate any of the packages described in the disclosure.

It should be noted that the method 1300 of FIG. 13 may combine one or more processes in order to simplify and/or clarify the method for providing or fabricating a package. In some implementations, the order of the processes may be changed or modified.

The method provides (at 1305) a substrate comprising at least one dielectric layer and a plurality of interconnects. Stage 1 of FIG. 12A, illustrates and describes an example of a state after a substrate 501 is fabricated and/or provided. The substrate 501 includes at least one dielectric layer 520 and a plurality of interconnects 523.

The method forms (at 1310) a cavity in the substrate. Stage 2 of FIG. 12A, illustrates and describes an example of a state after a cavity 1210 is formed in the substrate 501. A laser process may be used to form the cavity 1210.

The method places and couples (at 1315) one or more devices in and/or to the cavity of the substrate. Stage 3 of FIG. 12A, illustrates and describes a state after the device 306 is placed in the cavity 1210 and coupled to the substrate 501 through an adhesive 560. The back side of the device 306 may be coupled to the substrate 501 through the adhesive 560. The device 306 may represent the passive device 100 or the active device 200.

The method forms (at 1320) additional dielectric layer and interconnects in the substrate. Stage 4 of FIG. 12B, illustrates and describes an example of a state after a dielectric layer 1220 is formed and coupled to the dielectric layer 520 and the device 306. A deposition process and/or a lamination process may be used to form the dielectric layer 1220. The dielectric layer 1220 may be formed in the cavity 1210 of the substrate 501. The dielectric layer 1220 may be considered part of the dielectric layer 520.

Stage 5 of FIG. 12B, illustrates and describes an example of a state after a plurality of interconnects 1253 are formed in and/or on the substrate 501. A plurality of cavities may be formed in the substrate 501. A plating process may be used to form the plurality of interconnects 1253. The plurality of interconnects 1253 may be coupled to the plurality of interconnects 523. The plurality of interconnects 1253 may be considered part of the plurality of interconnects 523.

The method couples (at 1325) a plurality of integrated devices to the substrate. Stage 6 of FIG. 12B, illustrates and describes an example of a state after a plurality of integrated devices are coupled to the substrate. The integrated device 303a may be coupled to the plurality of interconnects 523 of the substrate 501 through a plurality of pillar interconnects 331a and/or a plurality of solder interconnects 334a. The integrated device 303b may be coupled to the plurality of interconnects 523 of the substrate 501 through a plurality of pillar interconnects 331b and/or a plurality of solder interconnects 334b. A solder reflow process may be used to couple the plurality of integrated devices to the substrate 501.

The method forms (at 1330) an encapsulation layer that is coupled to the substrate. Stage 7 of FIG. 12C, illustrates and describes an example of a state after an encapsulation layer 309 is provided and coupled to the substrate 501. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may be over molded and grinded off (e.g., partially removed). The encapsulation layer 309 may at least partially encapsulate the integrated device 303a and the integrated device 303b.

The method couples (at 1335) a plurality of solder interconnects to the substrate. Stage 8 of FIG. 12C, illustrates and describes an example of a state after a plurality of solder interconnects 114 are coupled to the substrate 501. The plurality of solder interconnects 114 may be coupled to the plurality of interconnects 523 of the substrate 501.

### Exemplary Sequence for Fabricating a Metallization Portion

In some implementations, fabricating a substrate includes several processes. FIGS. 14A-14B illustrate an exemplary sequence for providing or fabricating a metallization portion. In some implementations, the sequence of FIGS. 14A-14B may be used to provide or fabricate the metallization portion (e.g., 320, 340, 420, 440). However, the process of FIGS. 14A-14B may be used to fabricate any of the metallization portions described in the disclosure.

It should be noted that the sequence of FIGS. 14A-14B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 14A, illustrates a state after a carrier 1400 is provided. A seed layer 1401 may be located over the carrier 1400. The carrier 1400 may be replaced with other components and/or materials.

Stage 2 illustrates a state after a plurality of interconnects 1412 are formed. The interconnects 1412 may be located over the seed layer 1401. A lithography process, a plating process, a strip process and/or an etching process may be used to form the plurality of interconnects 1412. The interconnects 1412 may represent at least some of the interconnects from the plurality of metallization interconnects 123.

Stage 3 illustrates a state after a dielectric layer 1410 is formed over the carrier 1400, the seed layer 1401 and the plurality of interconnects 1412. A deposition and/or lamination process may be used to form the dielectric layer 1410. The dielectric layer 1410 may include prepreg and/or polyimide. The dielectric layer 1410 may include a photo-imageable dielectric. However, different implementations may use different materials for the dielectric layer.

Stage 4 illustrates a state after a plurality of cavities 1413 is formed in the dielectric layer 1410. The plurality of cavities 1413 may be formed using an etching process (e.g., photo etching process), a laser process, an exposure process and/or a development process.

Stage 5 illustrates a state after interconnects 1422 are formed in and over the dielectric layer 1410, including in and over the plurality of cavities 1413. For example, a via, pad and/or traces may be formed. A lithography process, a plating process, a strip process and/or an etching process may be used to form the interconnects.

Stage 6, as shown in FIG. 14B, illustrates a state after a dielectric layer 1420 is formed over the dielectric layer 1410 and the plurality of interconnects 1422. A deposition and/or lamination process may be used to form the dielectric layer 1420. The dielectric layer 1420 may include prepreg and/or polyimide. The dielectric layer 1420 may include a photo-imageable dielectric. However, different implementations may use different materials for the dielectric layer.

Stage 7, illustrates a state after a plurality of cavities 1423 is formed in the dielectric layer 1440. The dielectric layer 1440 may represent the dielectric layer 1410 and/or the dielectric layer 1420. The plurality of cavities 1423 may be formed using an etching process (e.g., photo etching process), a laser process, an exposure process and/or a development process.

Stage 8 illustrates a state after interconnects 1432 are formed in and over the dielectric layer 1440, including in and over the plurality of cavities 1423. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

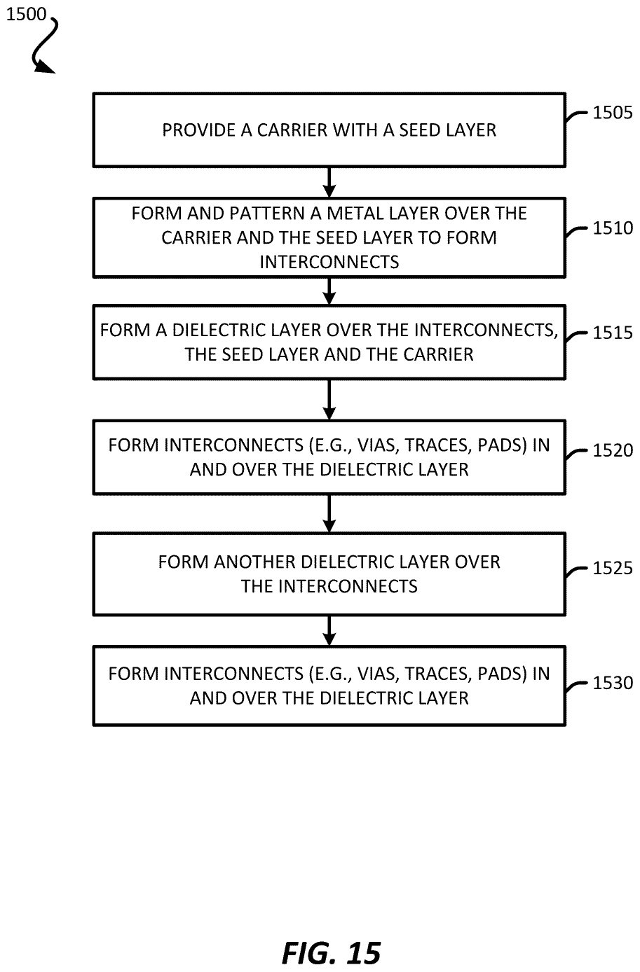

In some implementations, fabricating a substrate includes several processes. FIG. 15 illustrates an exemplary flow diagram of a method 1500 for providing or fabricating a metallization portion. In some implementations, the method 1500 of FIG. 15 may be used to provide or fabricate the metallization portion(s) of the disclosure. For example, the method 1500 of FIG. 15 may be used to fabricate the metallization portion (e.g., 320, 340, 420, 440).

It should be noted that the method 1500 of FIG. 15 may combine one or more processes in order to simplify and/or clarify the method for providing or fabricating a metallization portion. In some implementations, the order of the processes may be changed or modified.

The method provides (at 1505) a carrier with a seed layer. Stage 1 of FIG. 14A, illustrates and describes an example of a state after a carrier 1400 is provided. A seed layer 1401 may be located over the carrier 1400. The carrier 1400 may be replaced with other components and/or materials.

The method forms and patterns (at 1510) a plurality of interconnects. Stage 2 of FIG. 14A, illustrates and describes an example of a state after a plurality of interconnects 1412 are formed. The interconnects 1412 may be located over the seed layer 1401. A lithography process, a plating process, a strip process and/or an etching process may be used to form the plurality of interconnects 1412. The interconnects 1412 may represent at least some of the interconnects from the plurality of metallization interconnects 123.

The method forms (at 1510) a dielectric layer. Stage 3 of FIG. 14A, illustrates and describes an example of a state after a dielectric layer 1410 is formed over the carrier 1400, the seed layer 1401 and the plurality of interconnects 1412. A deposition and/or lamination process may be used to form the dielectric layer 1410. The dielectric layer 1410 may include prepreg and/or polyimide. The dielectric layer 1410 may include a photo-imageable dielectric. However, different implementations may use different materials for the dielectric layer.

The method forms (at 1520) a plurality of interconnects. Forming a plurality of interconnects may including forming a plurality of cavities in a dielectric layer and a performing a plating process. Stage 4 of FIG. 14A, illustrates and describes an example of a state after a plurality of cavities 1413 is formed in the dielectric layer 1410. The plurality of cavities 1413 may be formed using an etching process (e.g., photo etching process), a laser process, an exposure process and/or a development process.

Stage 5 of FIG. 14A, illustrates and describes an example of a state after interconnects 1422 are formed in and over the dielectric layer 1410, including in and over the plurality of cavities 1413. For example, a via, pad and/or traces may be formed. A lithography process, a plating process, a strip process and/or an etching process may be used to form the interconnects.

The method forms (at 1525) another dielectric layer. Stage 6 of FIG. 14B, illustrates and describes an example of a state after a dielectric layer 1420 is formed over the dielectric layer 1410 and the plurality of interconnects 1422. A deposition and/or lamination process may be used to form the dielectric layer 1420. The dielectric layer 1420 may include prepreg and/or polyimide. The dielectric layer 1420 may include a photo-imageable dielectric. However, different implementations may use different materials for the dielectric layer.

The method forms (at 1530) a plurality of interconnects. Forming a plurality of interconnects may including forming a plurality of cavities in a dielectric layer and a performing a plating process. Stage 7 of FIG. 14B, illustrates and describes an example of a state after a plurality of cavities 1423 is formed in the dielectric layer 1440. The dielectric layer 1440 may represent the dielectric layer 1410 and/or the dielectric layer 1420. The plurality of cavities 1423 may be formed using an etching process (e.g., photo etching process), a laser process, an exposure process and/or a development process.

Stage 8 of FIG. 14B, illustrates and describes an example of a state after interconnects 1432 are formed in and over the dielectric layer 1440, including in and over the plurality of cavities 1423. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

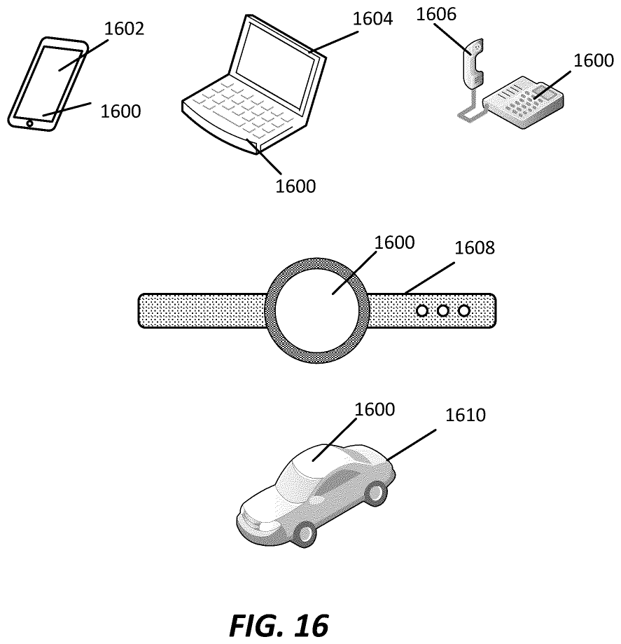

FIG. 16 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1602, a laptop computer device 1604, a fixed location terminal device 1606, a wearable device 1608, or automotive vehicle 1610 may include a device 1600 as described herein. The device 1600 may be, for example, any of the devices and/or integrated circuit (IC) packages described herein. The devices 1602, 1604, 1606 and 1608 and the vehicle 1610 illustrated in FIG. 16 are merely exemplary. Other electronic devices may also feature the device 1600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-7, 8A-8E, 9, 10A-10E, 11, 12A-12C, 13, 14A-14B and 15-16 may be rearranged and/or combined into a single component, process, feature or function or embodied in several components, processes, or functions. Additional elements, components, processes, and/or functions may also be added without departing from the disclosure. It should also be noted FIGS. 1-7, 8A-8E, 9, 10A-10E, 11, 12A-12C, 13, 14A-14B and 15-16 and its corresponding description in the present disclosure is not limited to dies and/or ICs. In some implementations, FIGS. 1-7, 8A-8E, 9, 10A-10E, 11, 12A-12C, 13, 14A-14B and 15-16 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. A seed layer may be considered part of an interconnect. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a package substrate comprising: at least one dielectric layer; a plurality of interconnects; a passive device located at least partially in the at least one dielectric layer, wherein the passive device comprises: a bridge comprising a plurality of bridge interconnects; and a capacitor comprising a plurality of capacitor interconnects that are vertically aligned; and an integrated device coupled to the package substrate.

Aspect 2: The package of aspect 1, wherein the passive device is further coupled to the integrated device.

Aspect 3: The package of aspect 1, wherein the passive device comprises a passive device substrate.

Aspect 4: The package of aspect 3, wherein the capacitor is located between the passive device substrate and the bridge.

Aspect 5: The package of aspect 3, wherein the passive device substrate comprises silicon.

Aspect 6: The package of aspect 3, wherein the plurality of capacitor interconnects include a plurality of capacitor via interconnects.

Aspect 7: The package of aspect 6, wherein the plurality of capacitor via interconnects include a plurality of anode capacitor via interconnects and a plurality of cathode capacitor via interconnects.

Aspect 8: The package of aspect 7, wherein the plurality of capacitor via interconnects are arranged in a matrix of capacitor via interconnects that alternate between an anode via interconnect and a cathode via interconnect.

Aspect 9: The package of aspect 3, wherein the passive device further comprises a device dielectric layer that is coupled to the passive device substrate.

Aspect 10: The package of aspect 1, wherein the passive device comprises a plurality of through substrate via interconnects.

Aspect 11: A package comprising a package interposer comprising: a first metallization portion; a second metallization portion; and a passive device located between the first metallization portion and the second metallization portion, wherein the passive device comprises: a bridge comprising a plurality of bridge interconnects; and a capacitor comprising a plurality of capacitor interconnects that are vertically aligned; and an integrated device coupled to the package interposer.

Aspect 12: The package of aspect 11, further comprising an encapsulation layer coupled to the first metallization portion and the second metallization portion, wherein the encapsulation layer at least partially encapsulates the passive device.

Aspect 13: The package of aspect 11, wherein the passive device comprises a passive device substrate.

Aspect 14: The package of aspect 13, wherein the capacitor is located between the passive device substrate and the bridge.

Aspect 15: The package of aspect 13, wherein the passive device substrate comprises silicon.

Aspect 16: The package of claim 13, wherein the plurality of capacitor interconnects include a plurality of capacitor via interconnects.

Aspect 17: The package of aspect 16, wherein the plurality of capacitor via interconnects include a plurality of anode capacitor via interconnects and a plurality of cathode capacitor via interconnects.

Aspect 18: The package of aspect 17, wherein the plurality of capacitor via interconnects are arranged in a matrix of capacitor via interconnects that alternate between an anode via interconnect and a cathode via interconnect.

Aspect 19: The package of aspect 13, wherein the passive device further comprises a dielectric layer that is coupled to the passive device substrate.

Aspect 20: The package of aspect 11, wherein the passive device comprises a plurality of through substrate via interconnects.

Aspect 21: A package comprising: a package interposer comprising: a first metallization portion; a second metallization portion; and an active device located between the first metallization portion and the second metallization portion, wherein the active device comprises: a memory; and a capacitor comprising a plurality of capacitor interconnects that are vertically aligned; and an integrated device coupled to the package interposer.

Aspect 22: The package of aspect 21, further comprising an encapsulation layer coupled to the first metallization portion and the second metallization portion, wherein the encapsulation layer at least partially encapsulates the active device.

Aspect 23: The package of aspect 21, wherein the memory comprises a plurality of memory logic cells, and wherein the active device comprises an active device substrate.

Aspect 24: The package of aspect 23, wherein the capacitor is located between the active device substrate and the memory.

Aspect 25: The package of aspect 23, wherein the active device substrate comprises silicon.

Aspect 26: The package of aspect 23, wherein the plurality of capacitor interconnects include a plurality of capacitor via interconnects.

Aspect 27: The package of aspect 26, wherein the plurality of capacitor via interconnects include a plurality of anode capacitor via interconnects and a plurality of cathode capacitor via interconnects.

Aspect 28: The package of aspect 27, wherein the plurality of capacitor via interconnects are arranged in a matrix of capacitor via interconnects that alternate between an anode via interconnect and a cathode via interconnect.

Aspect 29: The package of aspect 23, wherein the active device further comprises a dielectric layer that is coupled to the active device substrate.

Aspect 30: The package of aspect 21, wherein the active device comprises a plurality of through substrate via interconnects.

Aspect 31: A package comprising: a package substrate comprising: at least one dielectric layer; a plurality of interconnects; an active device located at least partially in the at least one dielectric layer, wherein the active device comprises: a memory; and a capacitor comprising a plurality of capacitor interconnects that are vertically aligned; and an integrated device coupled to the package substrate and the active device.

Aspect 32: The package of aspect 31, wherein the memory comprises a plurality of memory logic cells.

Aspect 33: The package of aspect 31, wherein the active device comprises an active device substrate.

Aspect 34: The package of aspect 33, wherein the memory is located between the active device substrate and the capacitor.

Aspect 35: The package of aspect 33, wherein the active device substrate comprises silicon.

Aspect 36: The package of aspect 33, wherein the plurality of capacitor interconnects include a plurality of capacitor via interconnects.

Aspect 37: The package of aspect 36, wherein the plurality of capacitor via interconnects include a plurality of anode capacitor via interconnects and a plurality of cathode capacitor via interconnects.

Aspect 38: The package of aspect 37, wherein the plurality of capacitor via interconnects are arranged in a matrix of capacitor via interconnects that alternate between an anode via interconnect and a cathode via interconnect.

Aspect 39: The package of aspect 33, wherein the active device further comprises a device dielectric layer that is coupled to the active device substrate.

Aspect 40: The package of aspect 31, wherein the active device comprises a plurality of through substrate via interconnects.

Aspect 41: The package of aspects 1 through 40, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a package substrate comprising:
at least one dielectric layer;
a plurality of interconnects;
a passive device located at least partially in the at least one dielectric layer,
wherein the passive device comprises:
a bridge comprising a plurality of bridge interconnects; and
a capacitor comprising a plurality of capacitor interconnects that are vertically aligned; and
an integrated device coupled to the package substrate.

2. The package of claim 1, wherein the passive device is further coupled to the integrated device.

3. The package of claim 1, wherein the passive device comprises a passive device substrate.

4. The package of claim 3, wherein the capacitor is located between the passive device substrate and the bridge.

5. The package of claim 3, wherein the passive device substrate comprises silicon.

6. The package of claim 3, wherein the plurality of capacitor interconnects include a plurality of capacitor via interconnects.

7. The package of claim 6, wherein the plurality of capacitor via interconnects include a plurality of anode capacitor via interconnects and a plurality of cathode capacitor via interconnects.

8. The package of claim 7, wherein the plurality of capacitor via interconnects are arranged in a matrix of capacitor via interconnects that alternate between an anode via interconnect and a cathode via interconnect.

9. The package of claim 3, wherein the passive device further comprises a device dielectric layer that is coupled to the passive device substrate.

10. The package of claim 1, wherein the passive device comprises a plurality of through substrate via interconnects.

11. A package comprising:
a package interposer comprising:
a first metallization portion;
a second metallization portion; and
a passive device located between the first metallization portion and the second metallization portion, wherein the passive device comprises:
a bridge comprising a plurality of bridge interconnects; and
a capacitor comprising a plurality of capacitor interconnects that are vertically aligned; and
an integrated device coupled to the package interposer.

12. The package of claim 11, further comprising an encapsulation layer coupled to the first metallization portion and the second metallization portion, wherein the encapsulation layer at least partially encapsulates the passive device.

13. The package of claim 11, wherein the passive device comprises a passive device substrate.

14. The package of claim 13, wherein the capacitor is located between the passive device substrate and the bridge.

15. The package of claim 13, wherein the passive device substrate comprises silicon.

16. The package of claim 13, wherein the plurality of capacitor interconnects include a plurality of capacitor via interconnects.

17. The package of claim 16, wherein the plurality of capacitor via interconnects include a plurality of anode capacitor via interconnects and a plurality of cathode capacitor via interconnects.

18. The package of claim 17, wherein the plurality of capacitor via interconnects are arranged in a matrix of capacitor via interconnects that alternate between an anode via interconnect and a cathode via interconnect.

19. The package of claim 13, wherein the passive device further comprises a dielectric layer that is coupled to the passive device substrate.

20. The package of claim 11, wherein the passive device comprises a plurality of through substrate via interconnects.
